(19) United States
(12) Patent Application Publication
(10) Pub. No.: US 2024/0372315 A1
(43) Pub. Date: Nov. 7, 2024

(54) SEMICONDUCTOR LIGHT EMITTING DEVICE

(71) Applicant: SONY GROUP CORPORATION, TOKYO (JP)

(72) Inventors: YOSHIRO TAKIGUCHI, TOKYO (JP); HISAYOSHI MOTOBAYASHI, TOKYO (JP)

(21) Appl. No.: 18/686,457

(22) PCT Filed: Mar. 25, 2022
(86) PCT No.: PCT/JP2022/014322

§ 371 Date: Feb. 26, 2024

(30) Foreign Application Priority Data
Sep. 14, 2021 (JP) 2021-149634

(51) Int. Cl. H01S 5/02208; H01S 5/00; H01S 5/0225; H01S 5/023

(52) U.S. Cl. CPC H01S 5/02208; H01S 5/0064; H01S 5/0225; H01S 5/023

(57) ABSTRACT

A configuration includes a semiconductor light emitting element (40) including at least one light emitting region, a first housing unit (10) on which the semiconductor light emitting element (40) is mounted, the first housing unit (10) including a wiring structure with which the semiconductor light emitting element (40) can be externally connected, and a second housing unit (30) having a lid shape, the second housing unit (30) including a light emission surface (32b) and a rough surface (31a) configured to be able to transmit light, the second housing unit (30) being bonded to the first housing unit (10).

### FIELD

The present disclosure relates to a semiconductor light emitting device having a semiconductor light emitting element such as a semiconductor laser element, and a method for producing a package of the semiconductor light emitting device.

### BACKGROUND

In recent years, high-power blue semiconductor lasers have been developed for laser processing. The blue semiconductor laser has high absorption efficiency with respect to metal, and can be applied to processing of a region that is difficult to be processed with an infrared semiconductor laser. Thus, the blue semiconductor laser is expected to be applied as a light source for a next-generation laser processing machine. Further, higher output and higher brightness are required to expand the usage to new applications.

In such a trend, in a package of a semiconductor light emitting device, for example, in a semiconductor laser for laser processing, it is important that a short-focus lens (microlens) can be applied and an array with high density can be made.

In addition, the blue semiconductor laser is different from an infrared high-power semiconductor laser for processing already used in industry, and in open air, the laser light decomposes siloxane in the atmosphere, and the siloxane adheres to emission end surfaces, whereby the laser element is caused to deteriorate. Thus, airtight sealing for preventing siloxane deposition is essential.

Further, when a light output is obtained in a lateral direction (direction parallel to the package mounting surface), it is possible to replace the existing infrared high-power semiconductor laser BAR with the blue semiconductor laser. In such a case, the design change of the light source module of the laser beam machine can be minimized and the development cost can be reduced, which is particularly preferable.

A new packaging technology capable of achieving airtight sealing, short focal length, and high density array disposition at the same time is required to expand the usage of a high-power blue semiconductor laser to the application in industrial fields such as laser processing as described above, and it is necessary to develop a semiconductor light emitting device and a package of the device corresponding to such a requirement.

Patent Literature 1 discloses a semiconductor light emitting device including a light emitting element, a first housing member and a second housing member that contain the light emitting element, at least one of the members having a wiring structure that electrically connects the light emitting element and the outside, and a conductive bonding section that bonds the first housing member and the second housing member and is electrically coupled to the wiring structure.

Specifically, the semiconductor device includes a light emitting element, a housing member that is the first housing member, and a cover that is the second housing member. The housing member has a recess, and the light emitting element is housed in the recess. The housing member and the cover are bonded via a bonding member, whereby the light emitting element is airtightly sealed.

### CITATION LIST

### Patent Literature

Patent Literature 1: WO 2020/162023 A

### SUMMARY

### Technical Problem

However, in the technology related to the semiconductor light emitting device described in Patent Literature 1, for example, it is necessary to mount a window of a cover section and a lid of the cover section in order, and the structure is complicated, having a large number of components, a large number of solder bonding parts, and a larger number of assembly processes. Thus, there is a problem that the components cost and the assembly cost increase.

The present disclosure has been made in view of such problems, and an object of the present disclosure is to provide a semiconductor light emitting device and a package of the device capable of reducing the number of components, realizing cost reduction with a simple configuration, and expanding the usage of a high-power blue semiconductor laser to the application in an industrial field such as laser processing.

### Solution to Problem

The present disclosure has been made to address the above mentioned problem. The first aspect is a semiconductor light emitting device that includes: a semiconductor light emitting element including at least one light emitting region; a first housing unit on which the semiconductor light emitting element is mounted, the first housing unit including a wiring structure with which the semiconductor light emitting element can be externally connected; and a second housing unit having a lid shape, the second housing unit including a light emission surface and a rough surface configured to be able to transmit light, the second housing unit being bonded to the first housing unit.

In the first aspect, the second housing unit may be provided with anti-reflection coating with respect to emitted light on one surface or both surfaces of the light emission surface.

In the first aspect, in the second housing unit, an inner corner formed by a top surface parallel to an optical axis and a side surface being orthogonal to each other may be formed to have a radius of curvature of 50 μm or more.

In the first aspect, a side surface forming the lid shape of the second housing unit may have a thickness of 200 μm or more.

In the first aspect, at least an outer periphery of a top surface of the second housing unit may be formed into a rough surface.

In the first aspect, at least an inner peripheral surface of the second housing unit excluding the light emission surface may be formed into the rough surface.

In the first aspect, the rough surface of the second housing unit may have an arithmetic average roughness Ra of 0.2 μm to 50 μm.

In the first aspect, the second housing unit may be provided with a lens or a diffraction element formed to be able to transmit emitted light, the lens or the diffraction element being coupled and fixed to the rough surface directly or via a holding tab.

In the first aspect, the second housing unit may be made of a glass material.

In the first aspect, the second housing unit may be made of a glass material and silicon.

In the first aspect, the first housing unit may have a ceramic substrate including the wiring structure in a single layer form or a stacked layer form.

In the first aspect, the first housing unit may have a ceramic substrate including the wiring structure in a single layer form or a stacked layer form, and the ceramic substrate may be provided with a wiring structure of a metal film having a thickness of 20 μm or more formed on a surface of the ceramic substrate.

In the first aspect, each of the first housing unit and the second housing unit may include a metal pattern or a metal pad formed in an annular shape formed on a peripheral edge of each of the first housing unit and the second housing unit, the metal pattern or the metal pad surrounding the semiconductor light emitting element and being capable of bonding the first housing unit and the second housing unit to each other, and the metal pattern or the metal pad may have a width of 100 μm or more and may have a radius of curvature of a corner of 100 μm or more.

In the first aspect, the metal pattern or the metal pad of each of the first housing unit and the second housing unit may be formed in such a manner that the first housing unit and the second housing unit can be bonded to each other by soldering or an adhesive.

In the first aspect, the metal pattern or the metal pad of each of the first housing unit and the second housing unit may be bonded and fixed with solder or a low-temperature sinterable fine particle metal and may be airtightly sealed.

In the first aspect, the first housing unit may be configured to dispose an outer metal pattern on an outer periphery of the metal pattern formed in an annular shape, form a groove between the metal pattern formed in an annular shape and the outer metal pattern, and suck and hold solder or an adhesive overflowing when the second housing unit is bonded.

In the first aspect, the first housing unit may be configured to dispose an inner metal pattern on an inner periphery of the metal pattern formed in an annular shape, form a groove between the metal pattern formed in an annular shape and the inner metal pattern, and suck and hold solder or an adhesive overflowing when the second housing unit is bonded.

In the first aspect, a positional relationship between the first housing unit, the second housing unit, a front window of the second housing unit, and the semiconductor light emitting element may be as follows:
when an optical axis is La, an upper vertical direction divergence angle of the optical axis La of emitted light is θa1, an upper vertical direction divergence angle of the optical axis La as viewed from outside air is θa2, a lower vertical direction divergence angle is θb2, and an ineffective region width is he,
ya1+yaw≤ha−he is satisfied for an upper side of the optical axis La, and
yb1+ybw≤hb−he is satisfied for a lower side of the optical axis La,
where
ya1 is a distance in a direction orthogonal to the optical axis La to an intersection of the emitted light forming the angle θa1 and an incident surface of the front window,
yb1 is a distance in a direction orthogonal to the optical axis La to an intersection of the emitted light forming the angle θb1 and the incident surface of the front window,
yaw is a distance in a direction orthogonal to the optical axis La from an intersection of the emitted light forming the angle θa1 and the incident surface to an intersection of the emitted light forming the angle θa2 and an emission surface of the front window, and
ybw is a distance in a direction orthogonal to the optical axis La from an intersection of the emitted light forming the angle θb1 and the incident surface to an intersection of the emitted light forming the angle θb2 and the emission surface,
when a front end surface of an upper surface of the second housing unit protrudes more than the front window,
a relation of yb1+ybw+yb2≤hs is satisfied for the lower side of the optical axis La,
where hs is a distance from the optical axis La to the upper surface of the second housing unit, yb2 is a distance in a direction orthogonal to the optical axis La from an intersection of the emitted light forming the angle θb2 and the emission surface to an intersection of the emitted light forming the angle θb2 and a perpendicular line of the front end surface of the first housing unit, and further
(θ_{FWHM})/2≤θa1 may be satisfied for the upper side of the optical axis La, and
(θ_{FWHM})/2≤θb2 may be satisfied for the lower side of the optical axis La,
where
θ_{FWHM} is a full width at half maximum of an oblique angle, θa1 is the upper vertical direction divergence angle of the optical axis La of the emitted light, and θb2 is the lower vertical direction divergence angle of the optical axis La as viewed from outside air.

In the first aspect, the positional relationship between the first housing unit, the second housing unit, the front window of the second housing unit, and the semiconductor light emitting element may satisfy
θe/2≤θa1 for the upper side of the optical axis La, and
θe/2≤θb2 for the lower side of the optical axis La.
θe is the full width at 1/e² of the radiation angle.

In the first aspect, the semiconductor light emitting element may be configured in such a manner that a wavelength of at least one light emitting point is different from a wavelength of another light emitting point.

In the first aspect, the semiconductor light emitting element may be configured to obtain emitted light from two surfaces

In the first aspect, the semiconductor light emitting element may be mounted on a submount formed by stacking a copper (Cu)/sintered aluminum nitride (AlN)/copper (Cu) material, and the submount may be mounted in the first housing unit.

A second aspect is a method for producing a package of a semiconductor light emitting device, the method including a step of stacking a plurality of layers of a spacer wafer processed into a hole having a rectangular shape, a first window glass wafer subjected to anti-reflection coating, a cover unit wafer processed into a hole having a rectangular shape, and a second window glass wafer subjected to anti-reflection coating in this order to form a stack, a step of forming a secondary wafer by slicing a center and an outer side of the hole formed in a rectangular shape in a stacking direction of the stack in the stacking direction; a step of metallizing the secondary wafer into an annular metal pattern, a step of performing a solder forming treatment of the metallized annular metal pattern, and a step of dicing both side ends of the rectangular hole of the spacer wafer into individual pieces.

Taking the aspects described above can reduce the number of components, realize cost reduction with a simple configuration, and expand the usage of a high-power blue semiconductor laser to the application in an industrial field such as laser processing.

### BRIEF DESCRIPTION OF DRAWINGS

FIG. 1 includes a plan view and a schematic sectional view of a first embodiment of a semiconductor light emitting device according to the present disclosure.

FIG. 2 includes a plan view, a side view, and a bottom view of a cover unit according to the first embodiment of the semiconductor light emitting device according to the present disclosure.

FIG. 3 is a sectional view of the cover unit according to the first embodiment of the semiconductor light emitting device according to the present disclosure.

FIG. 4 is a perspective view of each unit and the whole of the first embodiment of the semiconductor light emitting device according to the present disclosure.

FIG. 5 is a schematic sectional view of a second embodiment of the semiconductor light emitting device according to the present disclosure.

FIG. 6 is a perspective view of each unit and the whole of the second embodiment of the semiconductor light emitting device according to the present disclosure.

FIG. 7 includes a plan view and a schematic sectional view of a third embodiment of the semiconductor light emitting device according to the present disclosure.

FIG. 8 is a perspective view of each unit and the whole of the third embodiment of the semiconductor light emitting device according to the present disclosure.

FIG. 9 is a schematic sectional view of a fourth embodiment of the semiconductor light emitting device according to the present disclosure.

FIG. 10 is a perspective view of each unit and the whole of the fourth embodiment of the semiconductor light emitting device according to the present disclosure.

FIG. 11 includes a plan view and a schematic sectional view of a fifth embodiment of the semiconductor light emitting device according to the present disclosure.

FIG. 12 is a perspective view of each unit and the whole of the fifth embodiment of the semiconductor light emitting device according to the present disclosure.

FIG. 13 is a schematic sectional view of a sixth embodiment of the semiconductor light emitting device according to the present disclosure.

FIG. 14 is a schematic sectional view of a seventh embodiment of the semiconductor light emitting device according to the present disclosure.

FIG. 15 is an explanatory view of a step of producing the cover unit of the semiconductor light emitting device according to the present disclosure (part 1).

FIG. 16 is an explanatory view of a step of producing the cover unit of the semiconductor light emitting device according to the present disclosure (part 2).

FIG. 17 is an explanatory view of a step of producing the cover unit of the semiconductor light emitting device according to the present disclosure (part 3).

FIG. 18 is an explanatory view of a step of producing the cover unit of the semiconductor light emitting device according to the present disclosure (part 4).

FIG. 19 is an explanatory view of a step of producing the cover unit of the semiconductor light emitting device according to the present disclosure (part 5).

FIG. 20 is an explanatory view of a step of producing the cover unit of the semiconductor light emitting device according to the present disclosure (part 6).

FIG. 21 is an explanatory view of a step of producing the cover unit of the semiconductor light emitting device according to the present disclosure (part 7).

FIG. 22 is an explanatory view of a step of producing the cover unit of the semiconductor light emitting device according to the present disclosure (part 8).

FIG. 23 is an explanatory view of a step of producing the cover unit of the semiconductor light emitting device according to the present disclosure (part 9).

FIG. 24 is an explanatory view of a step of producing the cover unit of the semiconductor light emitting device according to the present disclosure (part 10).

FIG. 25 is an explanatory view of a step of producing the cover unit of the semiconductor light emitting device according to the present disclosure (part 11).

FIG. 26 is an explanatory view of a positional relationship of a light emission point in a package of the semiconductor light emitting device according to the present disclosure.

FIG. 27 is a diagram illustrating an example of a schematic configuration of a semiconductor light emitting device according to an eighth embodiment.

FIG. 28 is a diagram illustrating an inclination angle.

FIG. 29 is a graph illustrating an example of a relationship between an inclination angle and an optical axis shift amount.

FIG. 30 is a diagram illustrating an example of a method for producing a cover unit.

FIG. 31 is a diagram illustrating an example of a method for producing the cover unit.

FIG. 32 is a diagram illustrating an example of a method for producing the cover unit.

FIG. 33 is a diagram illustrating an example of a method for producing the cover unit.

FIG. 34 is a diagram illustrating an example of a method for producing the cover unit.

FIG. 35 is a diagram illustrating an example of a method for producing the cover unit.

FIG. 36 is a diagram illustrating an example of a schematic configuration of a semiconductor light emitting device according to a ninth embodiment.

FIG. 37 is a diagram illustrating an example of a schematic configuration of the semiconductor light emitting device according to the ninth embodiment.

FIG. 38 is a diagram illustrating an example of a method for producing a cover unit.

FIG. 39 is a diagram illustrating an example of a method for producing the cover unit.

FIG. 40 is a diagram illustrating an example of a method for producing the cover unit.

FIG. 41 is a diagram illustrating an example of a method for producing the cover unit.

FIG. 42 is a diagram illustrating an example of a method for producing the cover unit.

FIG. 43 is a diagram illustrating an example of an optical element formed on a window glass wafer.

FIG. 44 is a diagram illustrating an example of an optical element formed on a window glass wafer.

FIG. 45 is a diagram illustrating an example of an optical element formed on a window glass wafer.

FIG. 46 is a diagram illustrating an example of an optical element formed on a window glass wafer.

FIG. 47 is a diagram illustrating an example of an optical element formed on a window glass wafer.

FIG. 48 is a diagram illustrating an example of an optical element formed on a window glass wafer.

### DESCRIPTION OF EMBODIMENTS

Next, modes for carrying out the present disclosure (hereinafter, it is referred to as an “embodiment”) will be described in the following order with reference to the drawings. In the following drawings, the same or similar portions are denoted by the same or similar reference numerals. However, the drawings are schematic, and dimensional ratios and the like of each part do not necessarily coincide with actual ones. It is needless to say that the drawings include portions having different dimensional relationships and ratios.
1. First Embodiment of Semiconductor Light Emitting Device According to Present Disclosure
2. Second Embodiment of Semiconductor Light Emitting Device According to Present Disclosure
3. Third Embodiment of Semiconductor Light Emitting Device According to Present Disclosure
4. Fourth Embodiment of Semiconductor Light Emitting Device According to Present Disclosure
5. Fifth Embodiment of Semiconductor Light Emitting Device According to Present Disclosure
6. Sixth Embodiment of Semiconductor Light Emitting Device According to Present Disclosure
7. Seventh Embodiment of Semiconductor Light Emitting Device According to Present Disclosure
8. Method for Producing Package of Semiconductor Light Emitting Device According to Present Disclosure
9. Positional Relationship of Light Emission Point of Package in Semiconductor Light Emitting Device According to Present Disclosure
10. Eighth Embodiment of Semiconductor Light Emitting Device According to Present Disclosure
11. Ninth Embodiment of Semiconductor Light Emitting Device According to Present Disclosure

### 1. First Embodiment of Semiconductor Light Emitting Device According to Present Disclosure

### <Structure of Base Unit>

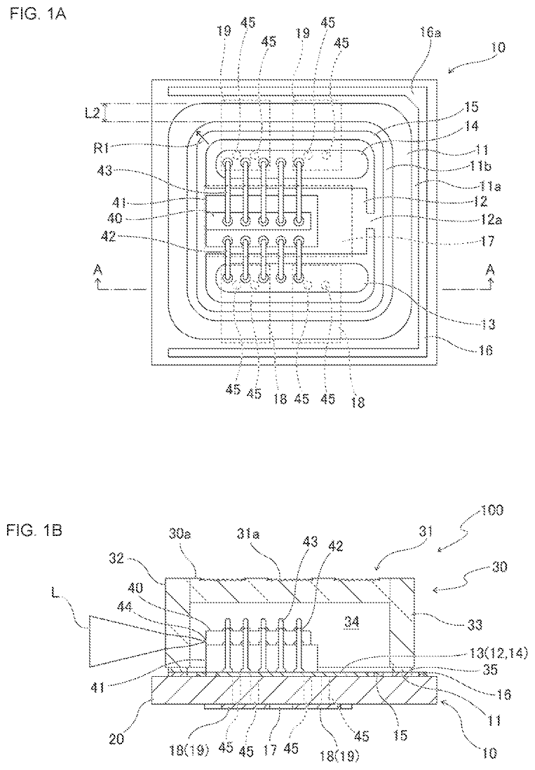

FIG. 1A is a plan view of a first embodiment of a semiconductor light emitting device 100 according to the present disclosure. A cover unit 30 illustrated in FIG. 1B is excluded from the drawing. FIG. 1B is a schematic sectional view as viewed in the direction A of FIG. 1A.

The semiconductor light emitting device 100 according to the present disclosure includes a semiconductor light emitting element 40, a first housing unit on which the semiconductor light emitting element 40 is mounted, the first housing unit having a wiring structure with which the semiconductor light emitting element 40 can be externally connected, and a second housing unit having a lid shape, the second housing unit having a light emission surface and being bonded to the first housing unit.

Here, the first housing unit is, for example, a base unit 10 on which the semiconductor light emitting element 40 is mounted and having a wiring structure thereof. The second housing unit is the cover unit 30 that covers the base unit 10 to airtightly seal the semiconductor light emitting element 40 and is capable of transmitting emitted light L to the outside. However, the first housing unit and the second housing unit are not limited to the base unit 10 and the cover unit 30 described below, and include those configured to house the semiconductor light emitting element 40 and emit the emitted light L.

First, the base unit 10 will be described. In the semiconductor light emitting device 100, as illustrated in FIGS. 1A and 1B, the cover unit 30 formed in a substantially square or rectangular shape in plan view is placed on the base unit 10 formed in a substantially square or rectangular shape in plan view, and they are bonded by soldering or the like.

The base unit 10 is made of, for example, sintered aluminum nitride (AlN), which is a ceramic material, and has a thickness of, for example, 300 μm. The base unit 10 is an insulator serving as a base of a package of the semiconductor light emitting device 100 according to the present disclosure. Sintered aluminum nitride (AlN) as a material of the base unit has high electrical insulation properties and high thermal conductivity, and thus it is excellent in heat dissipation effect.

On an outer peripheral edge of the base unit 10, an outer metal pattern 16 is disposed in a substantially U shape. When a cover bonding metal pattern 11 to be described later and the cover unit 30 are soldered, the outer metal pattern 16 sucks excessive solder overflowing to the outside of the soldering surface, holds the excessive solder overflowing to an outer groove 11a formed between the outer metal pattern 16 and the cover bonding metal pattern 11, and prevents solder from leaking to the outside from the outer periphery of the base unit 10. This configuration can prevent external dimension abnormality caused by the overflowed excessive solder and improves production yield.

As illustrated in FIG. 1A, a substantially triangular index mark 16a is formed at the upper right corner of the outer metal pattern 16. The index mark 16a is used to correctly recognize the orientation of the base unit 10 with image recognition in a production apparatus. This is particularly effective when the metal pattern on the surface has a line-symmetric shape.

On the inner side of the outer metal pattern 16, a cover bonding metal pattern 11 formed in a substantially square or rectangular shape in plan view and having rounded corners at four corners is annularly disposed to surround the semiconductor light emitting element 40 and a submount 41 mounted inside. The cover bonding metal pattern 11 is soldered or adhered to a base bonding solder pattern 35 of the cover unit 30 described later.

As illustrated in FIG. 1A, the cover bonding metal pattern 11 has a pattern width L2 of 100 μm or more, preferably 150 μm or more. A radius of curvature R1 of the four corners formed in the annular shape is 100 μm or more, preferably 200 μm or more. Forming the radius of curvature R1 to be larger than the predetermined dimension can prevent occurrence of material fracture such as a crack due to concentration of stress.

Further, on the inner side of the cover bonding metal pattern 11, an inner metal pattern 15 is annularly disposed in parallel with the cover bonding metal pattern 11 so as to surround the semiconductor light emitting element 40 and the like mounted inside. When the cover bonding metal pattern 11 and the base bonding solder pattern 35 of the cover unit 30 are soldered, the inner metal pattern 15 sucks excessive solder overflowing to the inside of the soldering surface, stops the excessive solder overflowing into an inner groove 11b formed between the inner metal pattern 15 and the cover bonding metal pattern 11, and prevents the excessive solder overflowing into the wire bond metal patterns 13 and 14 from coming into contact with the wire bond metal patterns. This configuration can prevent defects such as short circuits caused by excessive solder overflowing and can improve the production yield.

As illustrated in FIG. 1A, the inner metal pattern 15 is connected with a device mounting metal pattern 12 having a substantially rectangular shape that connects left and right sides of the pattern formed in an annular shape. That is, the left end of the device mounting metal pattern 12 is connected to the inner metal pattern 15 by the left side of the rectangle, and the right side is connected to the inner metal pattern 15 by a connection piece 12a. This causes the inner metal pattern 15 and the device mounting metal pattern 12 to be formed in a substantially squarish eight shape in plan view.

The device mounting metal pattern 12 is a metal pattern for mounting the submount 41 and the semiconductor light emitting element 40. That is, the submount 41 having a substantially rectangular shape is disposed in contact with the inner metal pattern 15 on the left side along the direction of the device mounting metal pattern 12. Further, on the upper surface of the submount 41, the semiconductor light emitting element 40 having a substantially rectangular shape is disposed along the direction of the submount 41.

The submount 41 is made of a material having a high thermal conductivity, such as silicon carbide (SiC), aluminum nitride (AlN), or copper tungsten (CuW). Titanium (Ti), platinum (Pt), or gold (Au) is used as the base metal. The upper surface is subjected to gold tin (AuSn) solder treatment for soldering the semiconductor light emitting element 40. The back surface of the submount 41 is soldered to the device mounting metal pattern 12 by gold tin (AuSn) solder.

The semiconductor light emitting element 40 is soldered by gold tin (AuSn) solder on the upper surface of the submount 41. As the semiconductor light emitting element 40, for example, gallium nitride (GaN)-based element, gallium arsenide (GaAs)-based element, indium phosphide (InP)-based element, or the like is used. Thus, the kind is not limited.

In an upper half region surrounded by the inner metal pattern 15 and the device mounting metal pattern 12, a rectangular n-electrode wire bond metal pattern 14 having both ends formed in a substantially semicircular shape is disposed. The n-electrode wire bond metal pattern 14 is bonded and connected to an n-type electrode of the semiconductor light emitting element 40 by one or more n-electrode wires 43 made of gold (Au) or the like. In this drawing, an example in which connection is made by five n-electrode wires 43 is illustrated.

In a lower half region surrounded by the inner metal pattern 15 and the device mounting metal pattern 12, a rectangular p-electrode wire bond metal pattern 13 having both ends formed in a substantially semicircular shape is disposed. The p-electrode wire bond metal pattern 13 is bonded and connected to a p-type electrode of the semiconductor light emitting element 40 by one or more p-electrode wires 42 made of gold (Au) or the like. In this drawing, an example in which connection is made by five p-electrode wires 42 is illustrated.

On the back surface of a base unit 20, a heat dissipation metal pattern 17 is disposed at a corresponding position on the back surface of the device mounting metal pattern 12. Heat generated by energization and light emission of the semiconductor light emitting element 40 is transferred to the heat dissipation metal pattern 17 via the submount 41 and the base unit 20. The semiconductor light emitting device 100 is soldered to a board or the like (not illustrated) to be mounted, and thus, heat is transferred to a heat sink or the like via a heat dissipation pattern of the board or the like and is dissipated.

On the back surface of the base unit 20, a p-electrode metal pattern 18 and an n-electrode metal pattern 19 are disposed at corresponding positions on the back surfaces of the p-electrode wire bond metal pattern 13 and the n-electrode wire bond metal pattern 14, respectively. The p-electrode wire bond metal pattern 13 and the n-electrode wire bond metal pattern 14 are connected to the p-electrode metal pattern 18 and the n-electrode metal pattern 19 through vias 45 and 45, respectively. The approximate diameter of the via 45 is, for example, about 50 μm to 250 μm. However, the diameter not limited. The number of vias 45 disposed in each electrode may be, for example, 2 to 3 per electrode, but an appropriate number of the bias may be disposed according to the material of the base unit 20 and the magnitude of the consumption current of the semiconductor light emitting element 40. It is preferable to dispose the vias 45 so as to be as close as possible to the p-electrode wire 42 and the n-electrode wire 43 but avoid the position immediately below the wires to reduce the wiring resistance. The same applies to other embodiments described later.

With such a configuration, the anode side of the semiconductor light emitting element 40 is electrically connected to the p-type electrode of the semiconductor light emitting element 40 by gold tin (AuSn) solder from the p-electrode metal pattern 18 via the via 45, the p-electrode wire bond metal pattern 13, the p-electrode wire 42, and the submount 41. The cathode side of the semiconductor light emitting element 40 is electrically connected from the n-type electrode of the semiconductor light emitting element 40 to the n-electrode metal pattern 19 via the n-electrode wire 43, the n-electrode wire bond metal pattern 14, and the via 45. As a result, an electric circuit extending from the p-electrode metal pattern 18 to the n-electrode metal pattern 19 is formed. The p-electrode metal pattern 18 and the n-electrode metal pattern 19 are solder-connected to corresponding polarities of a power supply system of a board or the like (not illustrated) to be mounted.

In the example of the base unit 10, the case where the base unit 20 is sintered aluminum nitride (AlN), which is a single-layer ceramic, has been described, but a multilayer ceramic material may be used when the wiring structure of the metal pattern is complicated. Wiring is facilitated by forming the wiring structure of the metal pattern in an inner layer, and the width of the metal pattern can be widened, and thus, the current capacity can be increased, the temperature rise can be prevented, and the heat dissipation can be improved. In addition, insulation properties can be improved.

Since the base unit 10 is configured as described above, it is possible to prevent excessive solder from leaking to the outside when the cover unit 30 is soldered to the base unit 10 by the outer metal pattern 16, the outer groove 11a, the inner metal pattern 15, and the inner groove 11b. This makes it possible to ensure insulation and improve the appearance of the product, not impairing the commercial value.

In addition, since the wiring of the semiconductor light emitting element 40 is penetratingly connected between the p-electrode wire bond metal pattern 13 and the p-electrode metal pattern 18 and between the n-electrode wire bond metal pattern 14 and the n-electrode metal pattern 19 by the vias 45 and 45, the wiring can be performed with an extremely simple configuration, and the cost can be reduced.

In addition, since heat generated by the semiconductor light emitting element 40 is transferred to the heat dissipation metal pattern 17 via the base unit 20 made of gold tin (AuSn) solder on the upper surface of the submount 41, the device mounting metal pattern 12, and sintered aluminum nitride (AlN) having excellent thermal conductivity, thermal resistance can be reduced. This makes it possible to reduce a temperature rise of the semiconductor light emitting element 40, and thus, reliability is improved, and a long life is realized.

### <Structure of Cover Unit>

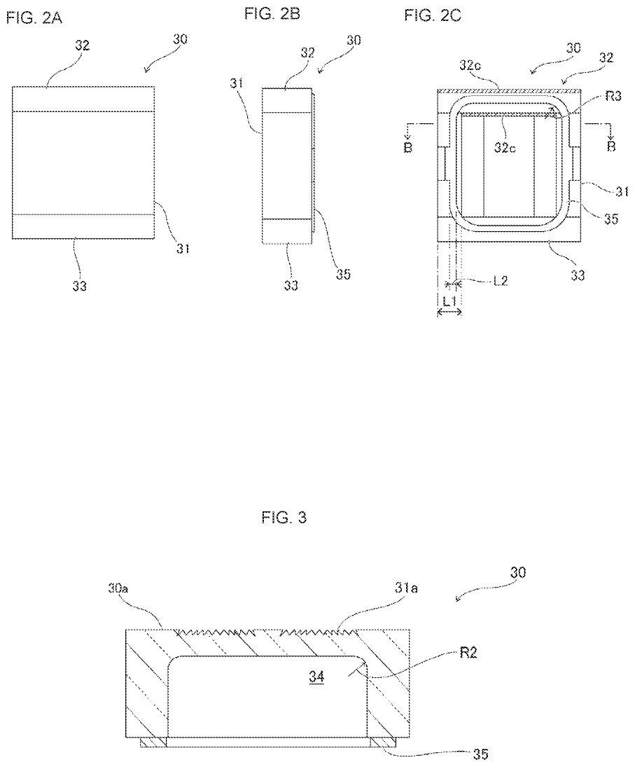

As illustrated in the schematic sectional view of FIG. 1B, the plan view of FIG. 2A, the right side view of FIG. 2B, and the bottom view of FIG. 2C, the cover unit 30 is formed in a substantially rectangular shape and a substantially lid shape with the lower side opened. The cover unit 30 includes a body 31, a front window 32, and a rear window 33, each of which is formed of a light transmissive material that transmits the emitted light L of the semiconductor light emitting element 40. As the light transmissive material, for example, glass is used. The front window 32 and the rear window 33 may be formed of glass having optical transparency, and the others may be formed of silicon or the like.

The body 31 of the cover unit 30 is formed in a substantially rectangular shape in plan view, and a cross section of the cover unit as viewed in the direction B of FIG. 2C is formed in a substantially U shape having a recess and is open downward as illustrated in the sectional view of FIG. 3 to constitute a frame of the cover unit 30. An outer surface of a bonding part between the top surface 30a having a substantially U shape in a sectional view and both side surfaces is formed at a right angle, and a corner of the inner surface is formed in a curved surface.

A radius of curvature R2 of the curved surface of the corner of the inner surface is preferably 50 μm or more. Since this curved surface is processed by sandblasting or drilling, the process is facilitated by setting the predetermined radius of curvature R2. In addition, by having such a radius of curvature R2, it is possible to prevent stress from concentrating at the corner and generating cracks.

As illustrated in FIG. 1B, a rough surface 31a is formed on the top surface 30a of the cover unit 30. By having the rough surface 31a, for example, when a lens 51 is adhered to the top surface 30a via a tab 52, which is a small glass piece, a good anchor effect can be obtained in the adhesive. To obtain a good anchor effect, the arithmetic average roughness Ra of the rough surface 31a is 0.2 μm to 50 μm, preferably 0.2 μm to 5 μm.

As illustrated in FIG. 2C, the front window 32 and the rear window 33 of the cover unit 30 are disposed on the upper surface (it becomes the front surface in use) and the lower surface (it becomes the rear surface in use) of the body 31, respectively, and constitute windows that transmit the emitted light L of the semiconductor light emitting element 40.

Anti-reflection (AR) coating 32c with respect to the emitted light L is applied to one surface or both surfaces of a light emission surface of the glass of the front window 32 and the rear window 33. The anti-reflection coatings 32c and 32c in this drawing illustrate an example in which both surfaces of the front window 32 are treated when the front window 32 is an emission surface. When light is emitted from both the front window 32 and the rear window 33 (that is, when the emitted light L is output in two directions), the rear window 33 is also subjected to the same treatment as the anti-reflection coating 32c of the front window 32. In the following drawings, description of the anti-reflection coating 32c is omitted.

The front window 32 and the rear window 33, which are subjected to the anti-reflection coating 32c process as described above, are bonded to the body 31 by optical contact.

In this manner, the cover unit 30 is configured by bonding the front window 32 and the rear window 33 to the body 31. As a result, a cavity 34, which is a recess surrounding the top surface 30a, both side surfaces, and the front and rear surfaces, is formed in the cover unit 30. Thus, as described later, when the cover unit 30 is bonded to the base unit 10, the semiconductor light emitting element 40 and the submount 41 are closed and airtightly sealed in the cavity 34 as illustrated in FIG. 1B.

A base bonding solder pattern 35 having four corners is annularly formed on the peripheral surface of an opening of the cavity 34 on the bottom surface of the cover unit 30. The base bonding solder pattern 35 is a metal pattern for bonding with the cover bonding metal pattern 11 of the base unit 10. As the base metal of the base bonding solder pattern 35, a stacked alloy made of chromium (Cr), Ti (titanium), molybdenum (Mo), platinum (Pt), nickel (Ni), and gold (Au) is typically used. Further, gold tin (AuSn) solder treatment is performed thereon.

As illustrated in FIG. 2C, the base bonding solder pattern 35 is formed to have a pattern width L2 of 100 μm or more, preferably 150 μm or more. The width L1 of the side surface of the body 31 is formed to be 100 μm or more, preferably 200 μm or more. A radius of curvature R3 of the four corners formed in the annular shape is 100 μm or more, preferably 200 μm or more. These values need to be adjusted to be bonded to the cover bonding metal pattern 11 of the base unit 10.

From experience, when the cover unit 30 is bonded to the base unit 10, it is ensured that the airtight sealing property is maintained by forming the cover to have such dimensions.

### <Overall Configuration of Base Unit and Cover Unit>

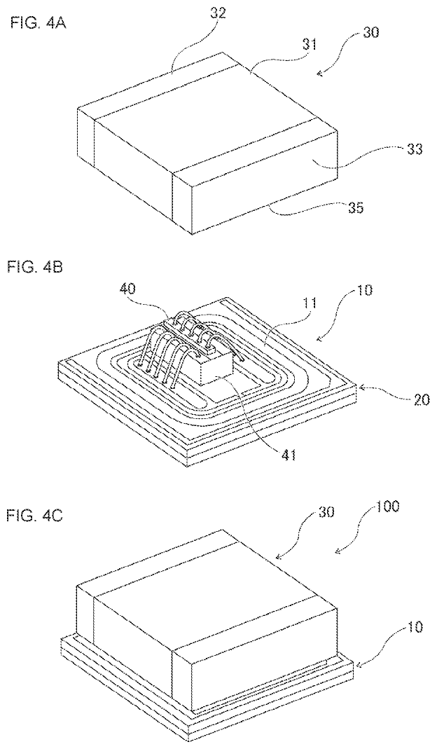

As illustrated in FIGS. 4A, 4B, and 4C, the cover unit 30 is bonded to the base unit 10 by gold tin (AuSn) solder, whereby the semiconductor light emitting device 100 according to the present embodiment can be completed.

That is, the base unit 10 and the cover unit 30 can be bonded by bringing the base bonding solder pattern 35 of the cover unit 30 into contact with the cover bonding metal pattern 11 of the base unit 10 and performing gold tin (AuSn) solder bonding. Tin-silver-copper (SnAgCu) may be used for solder bonding.

The cover bonding metal pattern 11 and the base bonding solder pattern 35 may be bonded by an adhesive. The cover bonding metal pattern 11 and the base bonding solder pattern 35 may be bonded by low-temperature sinterable fine particle metal.

In the above description, an example in which one semiconductor light emitting element 40 is mounted on the base unit 10 has been described, but the number of the semiconductor light emitting elements 40 is not limited to one. For example, three or four sets of the device mounting metal pattern 12, the p-electrode wire bond metal pattern 13, and the n-electrode wire bond metal pattern 14 may be disposed on one base unit 10, and the semiconductor light emitting element 40 may be mounted on each base unit via the submount 41.

The wavelength of each of these three or four sets of semiconductor light emitting elements 40 may be, for example, 455 nm, 525 nm, or 635 nm (as three primary color light sources for a projector). Alternatively, the wavelength may be 435, 445 nm, 455 nm, or 465 nm (as a wavelength multiplexing light source of a laser beam machine). Alternatively, the wavelength may be 915 nm, 940 nm, or 975 nm (as a light source for solid-state laser excitation).

By mounting the semiconductor light emitting elements 40 in multiple manners like this, miniaturization and high integration can be achieved without cost, and thus the use range can be further expanded.

Since the semiconductor light emitting device 100 according to the present embodiment is configured as described above, it is possible to provide a package of an airtightly sealed semiconductor light emitting device capable of reducing the number of components, realizing cost reduction with a simple configuration, and expanding the usage of a high-power blue semiconductor laser to an industrial field such as laser processing.

### 2. Second Embodiment of Semiconductor Light Emitting Device According to Present Disclosure

The semiconductor light emitting device 100 according to the present embodiment is obtained by attaching a lens unit 50 to the semiconductor light emitting device 100 according to the first embodiment.

### <Structure of Base Unit>

The structure of the base unit 10 of the semiconductor light emitting device 100 according to the present embodiment is the same as that of the first embodiment. Thus, description thereof is omitted.

### <Structure of Cover Unit>

The structure of the cover unit 30 of the semiconductor light emitting device 100 according to the present embodiment is the same as that of the first embodiment. Thus, description thereof is omitted.

### <Overall Configuration of Base Unit and Cover Unit>

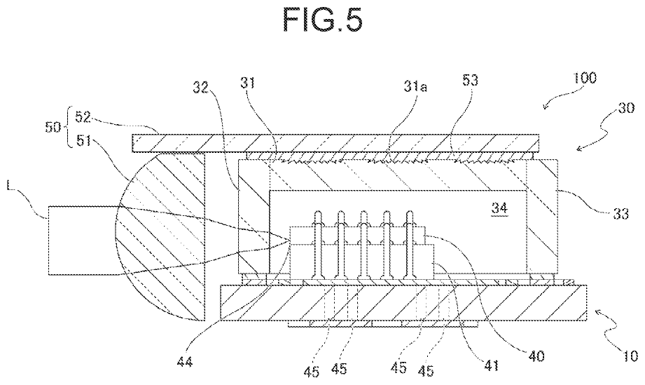

In the present embodiment, as illustrated in FIG. 5, the lens unit 50 is attached to the rough surface 31a of the top surface 30a of the cover unit 30 of the semiconductor light emitting device 100 according to the first embodiment.

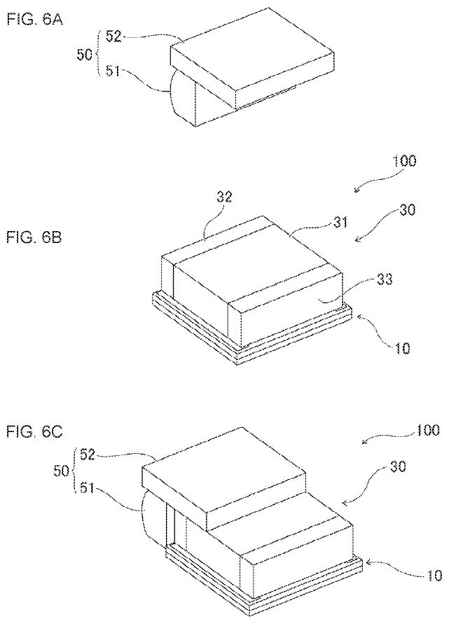

Specifically, as illustrated in FIG. 6A, the lens unit 50 includes a tab 52 made of glass formed in a substantially thin rectangular shape, and a lens 51 that is a plano-convex lens made of glass formed in a substantially semi-cylindrical shape. Then, the upper surface of the lens 51 is adhered to the tip edge of the tab 52. Adhesion between the tab 52 and the lens 51 is performed by an adhesive. In addition, glass welding may be used, or bonding may be performed by soldering after metallizing. In any case, the method for adhering or bonding the two is not limited to a specific method.

A diffraction element such as a diffraction grating may be used instead of the lens 51 or together with the lens 51. As a result, a filter effect or the like can be obtained.

Next, the semiconductor light emitting device 100 in which the cover unit 30 is bonded to the base unit 10 as illustrated in FIG. 6B is prepared. The semiconductor light emitting device 100 illustrated in FIG. 6B is the same as the semiconductor light emitting device 100 illustrated in FIG. 4C.

Next, as illustrated in FIG. 6C, the tab 52 of the lens unit 50 is adhered to the rough surface 31a of the top surface 30a of the cover unit 30 such that the flat side of the lens 51 faces the front window 32 of the cover unit 30.

Adhesion is performed using an epoxy-based or acrylic-based adhesive 53. The semiconductor light emitting device 100 as illustrated in FIG. 5 can be thus configured.

The tab 52 is adhered such that the emission surface 44, which is the light emitting position of the semiconductor light emitting element 40, is at the focal position of the lens 51. The method for adhering or bonding the two is not limited to bonding with the adhesive 53.

One end of each of the two tabs 52 and 52 may be adhered to the left and right side surfaces of the lens 51, and the other end of each of the tabs 52 and 52 may be adhered to the left and right side surfaces of the cover unit 30 with the rough surface 31a. By adopting such an adhesive structure, the adhesion can be further strengthened. In addition, the height can be reduced. In the present embodiment, the lens 51 is a plano-convex lens, but it may be a biconvex lens or an uneven lens.

Since the semiconductor light emitting device 100 according to the second embodiment is configured as described above, it is possible to condense the emitted light L of the semiconductor light emitting element 40 by the action of the lens 51 to obtain high-luminance collimated light.

In addition, since the lens 51 is adhered to the rough surface 31a formed on the wide top surface 30a of the cover unit 30 via the tab 52 in a wide area, the adhesive force and the stability of adhering are high, and mounting can be performed with high accuracy.

### 3. Third Embodiment of Semiconductor Light Emitting Device According to Present Disclosure

The semiconductor light emitting device 100 according to the present embodiment is different from that of the first embodiment in that the emitted light L is output in two directions of front and rear directions. This will be described below.

### <Structure of Base Unit>

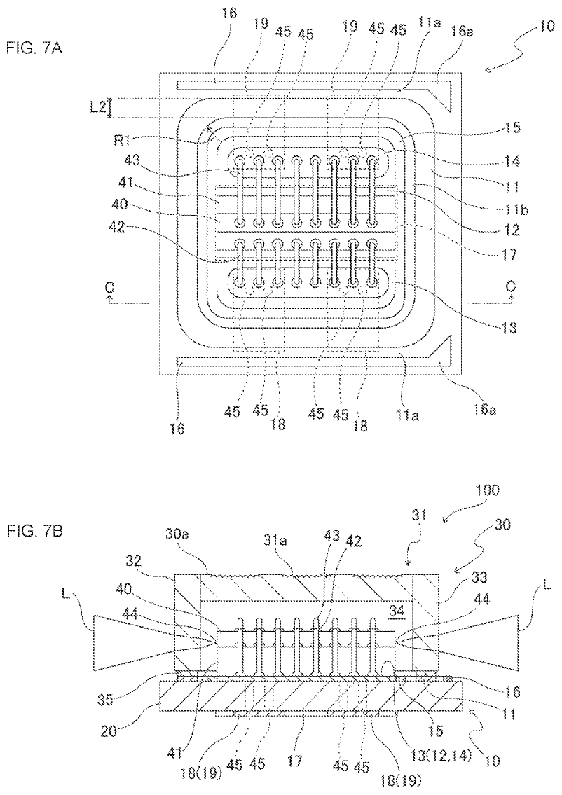

FIG. 7A is a plan view of the present embodiment. The cover unit 30 illustrated in FIG. 7B is excluded from the drawing. FIG. 7B is a schematic sectional view as viewed in the direction C of FIG. 7A.

The base unit 10 is made of sintered aluminum nitride (AlN) as in the first embodiment.

On an outer peripheral edge of the base unit 10, outer metal patterns 16 and 16 are disposed on both sides. When the cover bonding metal pattern 11 and the base bonding solder pattern 35 of the cover unit 30 are soldered, the outer metal patterns 16 and 16 suck excessive solder overflowing to the outside of the soldering surface, hold the excessive solder overflowing to an outer groove 11a formed between the outer metal pattern 16 and the cover bonding metal pattern 11, and prevent solder from leaking to the outside from the outer periphery of the base unit 10. To identify the orientation of the base unit 10, substantially triangular index marks 16a and 16a are formed at right corners of the outer metal patterns 16 and 16 as illustrated in FIG. 7A. The other details of the cover bonding metal pattern 11 are the same as those of the first embodiment.

On the inner side of the outer metal pattern 16, a cover bonding metal pattern 11 formed in a substantially square or rectangular shape in plan view and having rounded corners at four corners is annularly disposed to surround the semiconductor light emitting element 40 and a submount 41 mounted inside. The cover bonding metal pattern 11 is soldered to the base bonding solder pattern 35 of the cover unit 30 as in the first embodiment.

Further, on the inner side of the cover bonding metal pattern 11, an inner metal pattern 15 is annularly arranged in parallel with the cover bonding metal pattern 11 so as to surround the elements mounted inside. When the cover bonding metal pattern 11 and the cover unit 30 are soldered, the inner metal pattern 15 sucks excessive solder overflowing to the inside of the soldering surface, stops the excessive solder overflowing into an inner groove 11b formed between the inner metal pattern 15 and the cover bonding metal pattern 11, and prevents the excessive solder overflowing into the wire bond metal patterns 13 and 14 from coming into contact with the wire bond metal patterns.

As illustrated in FIG. 7A, in the inner metal pattern 15, the device mounting metal pattern 12 having a substantially rectangular shape that connects left and right sides of the pattern is formed in an annular shape. That is, the left end of the device mounting metal pattern 12 is connected to the left side of the inner metal pattern 15, and the right end is connected to the right side of the inner metal pattern 15. Thus, the inner metal pattern 15 and the device mounting metal pattern 12 are formed in a substantially squarish eight shape in plan view.

The device mounting metal pattern 12 is a metal pattern for mounting the submount 41 and the semiconductor light emitting element 40. That is, the substantially rectangular submount 41 is disposed along the direction of the device mounting metal pattern 12 connected to the left side and the right side of the inner metal pattern 15. Further, on the upper surface of the submount 41, the semiconductor light emitting element 40 having a substantially rectangular shape is disposed along the direction of the submount 41.

Since the material of the submount 41, the soldering treatment, and the like are the same as those of the first embodiment, the description thereof will be omitted.

Since the material of the semiconductor light emitting element 40, the soldering treatment, and the like are the same as those of the first embodiment, the description thereof will be omitted.

In an upper region surrounded by the inner metal pattern 15 and the device mounting metal pattern 12, a rectangular n-electrode wire bond metal pattern 14 having both ends formed in a substantially semicircular shape is disposed. The n-electrode wire bond metal pattern 14 is bonded and connected to an n-type electrode of the semiconductor light emitting element 40 by one or more n-electrode wires 43 made of gold (Au) or the like. In this drawing, an example in which connection is made by eight n-electrode wires 43 is illustrated.

In a lower region surrounded by the inner metal pattern 15 and the device mounting metal pattern 12, a rectangular p-electrode wire bond metal pattern 13 having both ends formed in a substantially semicircular shape is disposed. The p-electrode wire bond metal pattern 13 is bonded and connected to a p-type electrode of the semiconductor light emitting element 40 by one or more p-electrode wires 42 made of gold (Au) or the like. In this drawing, an example in which connection is made by eight p-electrode wires 42 is illustrated.

On the back surface of the base unit 20, a heat dissipation metal pattern 17 is disposed at a corresponding position on the back surface of the device mounting metal pattern 12. Heat generated by energization and light emission of the semiconductor light emitting element 40 is transferred to the heat dissipation metal pattern 17 via the submount 41 and the base unit 20. The semiconductor light emitting device 100 is soldered to a board or the like (not illustrated) to be mounted, and thus, heat is transferred to a heat sink or the like via a heat dissipation pattern of the board or the like and is dissipated.

On the back surface of the base unit 20, a p-electrode metal pattern 18 and an n-electrode metal pattern 19 are disposed at corresponding positions on the back surfaces of the p-electrode wire bond metal pattern 13 and the n-electrode wire bond metal pattern 14, respectively. The p-electrode wire bond metal pattern 13 and the n-electrode wire bond metal pattern 14 are connected to the p-electrode metal pattern 18 and the n-electrode metal pattern 19 through vias 45 and 45, respectively. The p-electrode metal pattern 18 and the n-electrode metal pattern 19 are solder-connected to corresponding polarities of a power supply system of a board or the like (not illustrated) to be mounted.

Thus, the configuration of the electric circuit from the p-electrode metal pattern 18 on the anode side to the n-electrode metal pattern 19 on the cathode side of the semiconductor light emitting element 40 is the same as that of the first embodiment, and thus, the description thereof is omitted. The effect of the base unit 10 is also same as that of the first embodiment, and thus the description thereof is omitted.

### <Structure of Cover Unit>

The structure of the cover unit 30 of the semiconductor light emitting device 100 according to the present embodiment is the same as that of the first embodiment. Thus, description thereof is omitted.

### <Overall Configuration of Base Unit and Cover Unit>

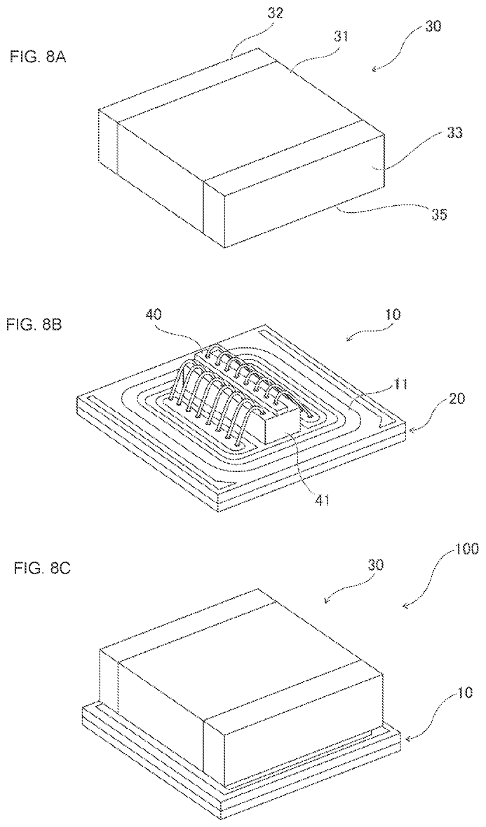

As illustrated in FIG. 8A, the present embodiment is different from the first embodiment in that the emitted light L is output in two front and rear directions.

Specifically, first, as illustrated in FIG. 8A, the cover unit 30 is prepared. The front window 32 and the rear window 33 of the cover unit 30 need to be made of a light transmissive material in order to transmit the emitted light L. Thus, the front window 32 and the rear window 33 are made of glass, for example. The other configurations are the same as those described in FIGS. 2, 3, and 4A of the first embodiment.

Next, as illustrated in FIG. 8B, the base unit 10 on which the submount 41 and the semiconductor light emitting element 40 for two-way output are mounted is prepared. The semiconductor light emitting element 40 for two-way output emits light in both directions of the front window 32 and the rear window 33.

Next, as illustrated in FIG. 8C, the cover unit 30 is bonded to the base unit 10 by gold tin (AuSn) solder, whereby the semiconductor light emitting device 100 according to the present embodiment can be completed.

That is, the base unit 10 and the cover unit 30 can be bonded by bringing the base bonding solder pattern 35 of the cover unit 30 into contact with the cover bonding metal pattern 11 of the base unit 10 and performing gold tin (AuSn) solder bonding. Tin-silver-copper (SnAgCu) may be used for solder bonding.

Since the semiconductor light emitting device 100 according to the present embodiment is configured as described above, it is possible to provide a package of an airtightly sealed semiconductor light emitting device 100 capable of reducing the number of components, realizing cost reduction with a simple configuration, and expanding the usage of a high-power blue semiconductor laser to an industrial field such as laser processing.

In addition, by adopting the two-way light output, the load on the end face of the emission surface 44 of the semiconductor light emitting element 40 can be halved.

In addition, a semiconductor optical amplifier (SOA) can be formed by appropriately selecting the dimension of the semiconductor light emitting element 40 in the resonator length direction.

### 4. Fourth Embodiment of Semiconductor Light Emitting Device According to Present Disclosure

The semiconductor light emitting device 100 according to the present embodiment is obtained by attaching lens units 50 and 50 in two directions of the semiconductor light emitting device 100 according to the third embodiment.

### <Structure of Base Unit>

The structure of the base unit 10 of the semiconductor light emitting device 100 according to the present embodiment is the same as that of the third embodiment. Thus, description thereof is omitted.

### <Structure of Cover Unit>

The structure of the cover unit 30 of the semiconductor light emitting device 100 according to the present embodiment is the same as that of the first embodiment. Thus, description thereof is omitted.

### <Overall Configuration of Base Unit and Cover Unit>

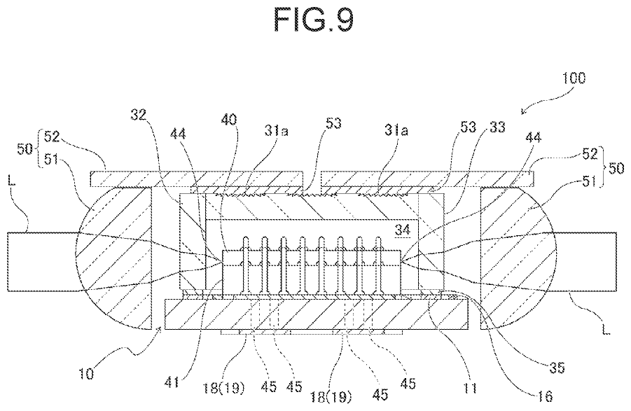

In the present embodiment, as illustrated in FIG. 9, lenses 51 and 51 are attached to the rough surface 31a of the top surface 30a of the cover unit 30 of the semiconductor light emitting device 100 according to the third embodiment in two directions via the tabs 52 and 52 of the lens units 50 and 50.

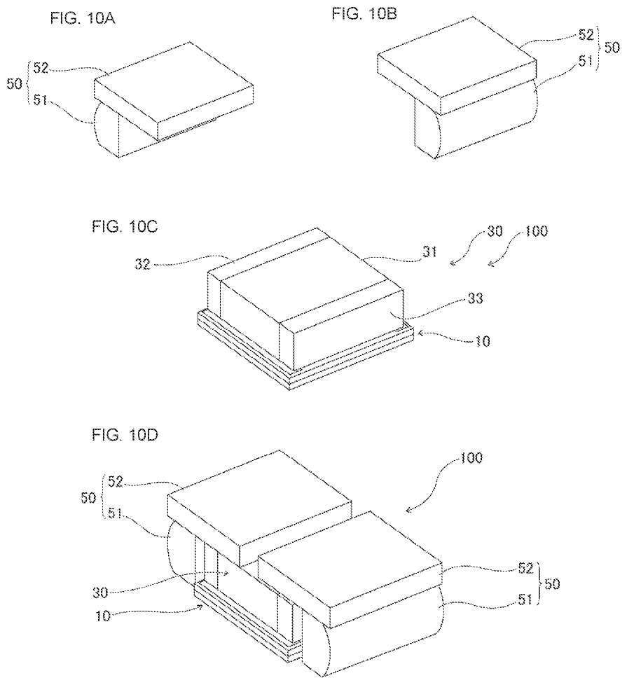

Specifically, first, as illustrated in FIGS. 10A and 10B, two sets of lens units 50 in which the upper surface of the lens 51 is adhered to the tip edge of the tab 52 are prepared. This is the same as in FIG. 6A of the second embodiment, and thus the description thereof is omitted.

Next, the semiconductor light emitting device 100 in which the cover unit 30 is bonded to the base unit 10 as illustrated in FIG. 10C is prepared. The semiconductor light emitting device 100 illustrated in FIG. 10C is the same as the semiconductor light emitting device 100 illustrated in FIG. 8C of the third embodiment.

Next, as illustrated in FIG. 10D, the tabs 52 and 52 are adhered to the rough surface 31a of the top surface 30a of the cover unit 30 such that the flat sides of the lenses 51 and 51 face the front window 32 and the rear window 33 of the cover unit 30, respectively. As in the second embodiment, adhesion is performed using the epoxy-based or acrylic-based adhesive 53. The semiconductor light emitting device 100 as illustrated in FIG. 9 can be thus configured.

The tabs 52 and 52 are adhered such that the emission surfaces 44 and 44, which are the respective light emission positions in the two directions of the semiconductor light emitting element 40, are at the focal positions of the respective lenses 51 and 51.

Since the semiconductor light emitting device 100 according to the fourth embodiment is configured as described above, it is possible to condense the emitted light L of the semiconductor light emitting element 40 by the action of the lens 51 to obtain high-luminance collimated light.

In addition, since the lens 51 is adhered to the rough surface 31a formed on the wide top surface 30a of the cover unit 30 via the tab 52 in a wide area, the adhesive force and the stability of adhering are high, and mounting can be performed with high accuracy. In addition, downsizing of an optical circuit using a semiconductor optical amplifier (SOA) can be realized.

### 5. Fifth Embodiment of Semiconductor Light Emitting Device According to Present Disclosure

In the semiconductor light emitting device 100 according to the present embodiment, a pattern formed on a base 66 is formed thicker as compared with other embodiments to form a pad.

### <Structure of Base Unit>

FIG. 11A is a plan view of a fifth embodiment of a semiconductor light emitting device 100 according to the present disclosure. The cover unit 30 illustrated in FIG. 11B is excluded from the drawing. FIG. 11B is a schematic sectional view as viewed in the direction D of FIG. 11A.

A base unit 60 is made of sintered aluminum nitride (AlN) as in the first embodiment.

To identify the orientation of the base unit 60, a substantially triangular index mark 66a is formed on the outer peripheral edge of the base unit 60 at the lower left corner of the base 66, as illustrated in FIG. 11A.

On the upper side of the base 66, a cover bonding pad 61 formed in a substantially square or rectangular shape in plan view and having rounded corners at four corners is annularly disposed to surround the semiconductor light emitting element 40 and the submount 41 mounted inside. The cover bonding pad 61 is soldered to the base bonding solder pattern 35 of the cover unit 30 as in a first example and the like. Details other than the thickness of the cover bonding pad 61 and the disposition of the pads described below are the same as those of the first embodiment.

On the inner side of the cover bonding pad 61, a device mounting pad 62 having an annular shape and a substantially rectangular shape in the left-right direction is disposed as illustrated in FIG. 11A. However, unlike other embodiments, the device mounting pad 62 is not coupled with the cover bonding pad 61.

The device mounting pad 62 is a pad for mounting the semiconductor light emitting element 40. The substantially rectangular submount 41 is disposed along the direction of the device mounting pad 62 in contact with the cover bonding pad 61 on the left side on the device mounting pad 62. Further, on the upper surface of the submount 41, the semiconductor light emitting element 40 having a substantially rectangular shape is disposed along the direction of the submount 41.

Since the submount 41, the semiconductor light emitting element 40, the soldering treatment thereof, and the like are the same as those in the first embodiment, the description thereof will be omitted.

In an upper region surrounded by the cover bonding pad 61 and the device mounting pad 62, a rectangular n-electrode wire bond pad 64 having both ends formed in a substantially semicircular shape is disposed. The n-electrode wire bond pad 64 is bonded and connected to an n-type electrode of the semiconductor light emitting element 40 by one or more n-electrode wires 43 made of gold (Au) or the like. In this drawing, an example in which connection is made by five n-electrode wires 43 is illustrated.

In a lower region surrounded by the cover bonding pad 61 and the device mounting pad 62, a rectangular p-electrode wire bond pad 63 having both ends formed in a substantially semicircular shape is disposed. The p-electrode wire bond pad 63 is bonded and connected to a p-type electrode of the semiconductor light emitting element 40 by one or more p-electrode wires 42 made of gold (Au) or the like. In this drawing, an example in which connection is made by five p-electrode wires 42 is illustrated.

On the back surface of the base 66, a heat dissipation pad 67 is disposed at a corresponding position on the back surface of the device mounting pad 62. Heat generated by energization and light emission of the semiconductor light emitting element 40 is transferred to the heat dissipation pad 67 via the submount 41 and the base 66. The semiconductor light emitting device 100 is soldered to a board or the like (not illustrated) to be mounted, and thus, heat is transferred to a heat sink or the like via a heat dissipation pattern of the board or the like and is dissipated.

On the back surface of the base 66, a p-electrode pad 68 and an n-electrode pad 69 are disposed at corresponding positions on the back surfaces of the p-electrode wire bond pad 63 and the n-electrode wire bond pad 64, respectively. The p-electrode wire bond pad 63 and the n-electrode wire bond pad 64 are connected to the p-electrode pad 68 and the n-electrode pad 69 through the vias 45 and 45, respectively.

Thus, the anode side of the semiconductor light emitting element 40 is electrically connected to the p-type electrode of the semiconductor light emitting element 40 by gold tin (AuSn) solder from the p-electrode pad 68 via the via 45, the p-electrode wire bond pad 63, the p-electrode wire 42, and the submount 41. On the other hand, the anode side of the semiconductor light emitting element 40 is electrically connected from the n-type electrode to the n-electrode pad 69 via the n-electrode wire 43, the n-electrode wire bond pad 64, and the via 45. An electric circuit from the p-electrode pad 68 to the n-electrode pad 69 is thus formed.

In addition, the pads on the front surface side, such as the cover bonding pad 61, the device mounting pad 62, the p-electrode wire bond pad 63, and the n-electrode wire bond pad 64, and the pads on the back surface side, such as the heat dissipation pad 67, the p-electrode pad 68, and the n-electrode pad 69, disposed on the base unit 60 are formed of copper (Cu), and the front surface thereof is plated with nickel/gold (Ni/Au). Further, the cover bonding pad 61 may have a thick metal pattern 61c on the base unit 60 side so as to have a convex shape in a section thereof, and may expand by about 50 μm on one side in a width direction.

That is, the base 66 is formed of a ceramic substrate made of sintered aluminum nitride (AlN) including a wiring structure such as the cover bonding pad 61 in a single layer form or a stacked layer form. The pad which is the wiring structure of the ceramic substrate is formed of a metal film such as copper (Cu) having a thickness of 20 μm or more. The thickness of the pad that is a wiring structure formed of copper (Cu) is preferably 20 μm or more. For example, the ratio between the thickness of copper (Cu) of each pad on the front surface side, the thickness of sintered aluminum nitride (AlN) of the base 66, and the thickness of copper (Cu) of each pad on the back surface side may be approximately 50 μm:200 μm:50 μm.

Since the base unit 60 is configured as described above, the cover bonding pad 61 of the base unit 60 and the base bonding solder pattern 35 of the cover unit 30 can be reliably soldered. At the time of solder bonding, since the overflowed excessive solder is adsorbed to the side surface portion of the cover bonding pad 61, it is possible to prevent generation of dust due to release of the excessive solder and to obtain favorable bonding. The case of having the metal pattern 61c is more preferable because the allowable amount of the solder adsorption amount increases.

In addition, the vias 45 penetrate and connect between the p-electrode wire bond pad 63 and the p-electrode pad 68 and between the n-electrode wire bond pad 64 and the n-electrode pad 69, and thus, wiring can be performed with an extremely simple configuration, and the cost can be reduced.

Further, since the device mounting pad 62 and the heat dissipation pad 67 are formed to be thick, thermal resistance can be reduced. With this configuration, heat generated by the semiconductor light emitting element 40 is transferred to the heat dissipation pad 67 via the gold tin (AuSn) solder excellent in thermal conductivity, the submount 41, the device mounting pad 62, and the base 66 made of sintered aluminum nitride (AlN), and thus, thermal resistance can be formed low. This makes it possible to reduce a temperature rise of the semiconductor light emitting element 40, and thus, reliability is improved, and a long life is realized.

### <Structure of Cover Unit>

The structure of the cover unit 30 of the semiconductor light emitting device 100 according to the present embodiment is the same as that of the first embodiment. Thus, description thereof is omitted.

### <Overall Configuration of Base Unit and Cover Unit>

In the semiconductor light emitting device 100 according to the present embodiment, a pattern (pad) formed on the base 66 is formed thicker as compared with other embodiments. Thus, the structure of the base unit 60 is different.

Specifically, first, as illustrated in FIG. 12A, the cover unit 30 is prepared. The other structure of the cover unit 30 is the same as those described in FIGS. 2, 3, and 4A of the first embodiment.

Next, as illustrated in FIG. 12B, the base unit 60 on which the submount 41 and the semiconductor light emitting element 40 mounted on the upper surface of the submount 41 are mounted is prepared.

Next, as illustrated in FIG. 12C, the cover unit 30 is bonded to the base unit 60 by gold tin (AuSn) solder, whereby the semiconductor light emitting device 100 according to the present embodiment can be completed.

That is, the base unit 60 and the cover unit 30 can be bonded by bringing the base bonding solder pattern 35 of the cover unit 30 into contact with the cover bonding pad 61 of the base unit 60 and performing gold tin (AuSn) solder bonding. Tin-silver-copper (SnAgCu) may be used for solder bonding.

Since the semiconductor light emitting device 100 according to the present embodiment is configured as described above, it is possible to provide a package of an airtightly sealed semiconductor light emitting device capable of reducing the number of components, realizing cost reduction with a simple configuration, and expanding the usage of a high-power blue semiconductor laser to an industrial field such as laser processing.

By increasing the thickness of the copper (Cu) layer constituting the pad, the effective thermal resistance of the base unit 60 can be reduced, and the heat dissipation can be improved to prevent temperature rise.

By adjusting the balance between the thicknesses of the base 66 and the copper (Cu) layer constituting each pad, the effective linear thermal expansion coefficient of the base unit 60 can be made close to the linear thermal expansion coefficient of the cover unit 30, and fracture of the cover unit 30, the base unit 60, and the bonding member due to the mismatch of the linear thermal expansion coefficients can be prevented.

### 6. Sixth Embodiment of Semiconductor Light Emitting Device According to Present Disclosure

In the semiconductor light emitting device 100 according to the present embodiment, the material of the submount 41 is changed from sintered aluminum nitride (AlN) to a CAC (Cu/AlN/Cu) material to form a CAC submount 46 as compared with other embodiments.

### <Structure of Base Unit>

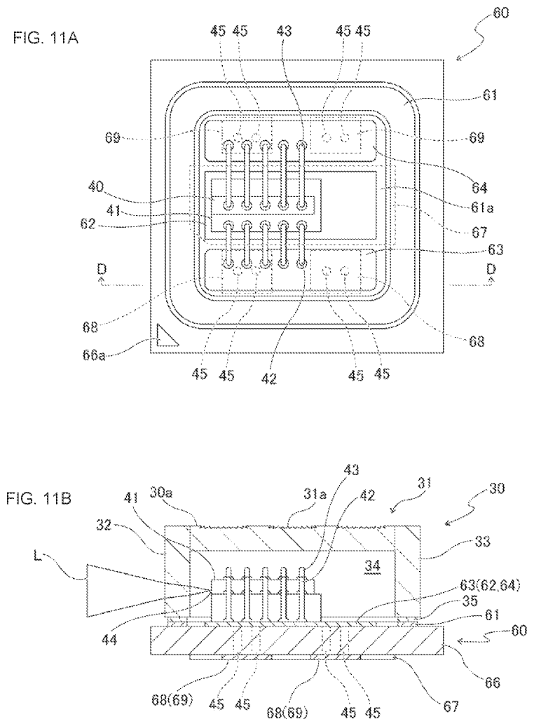

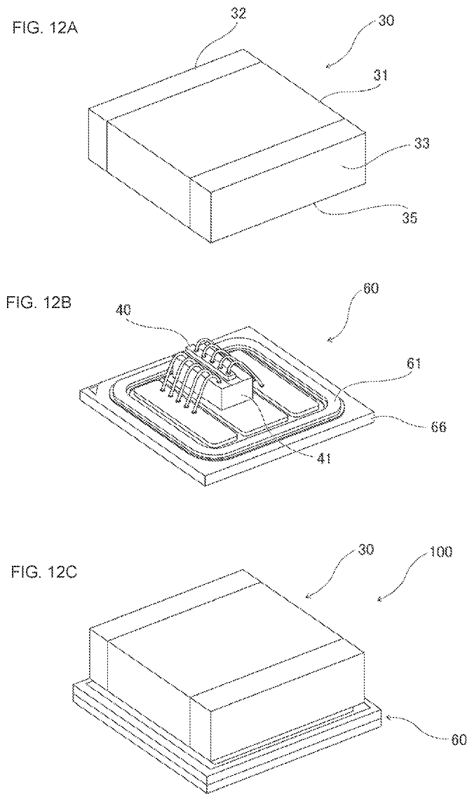

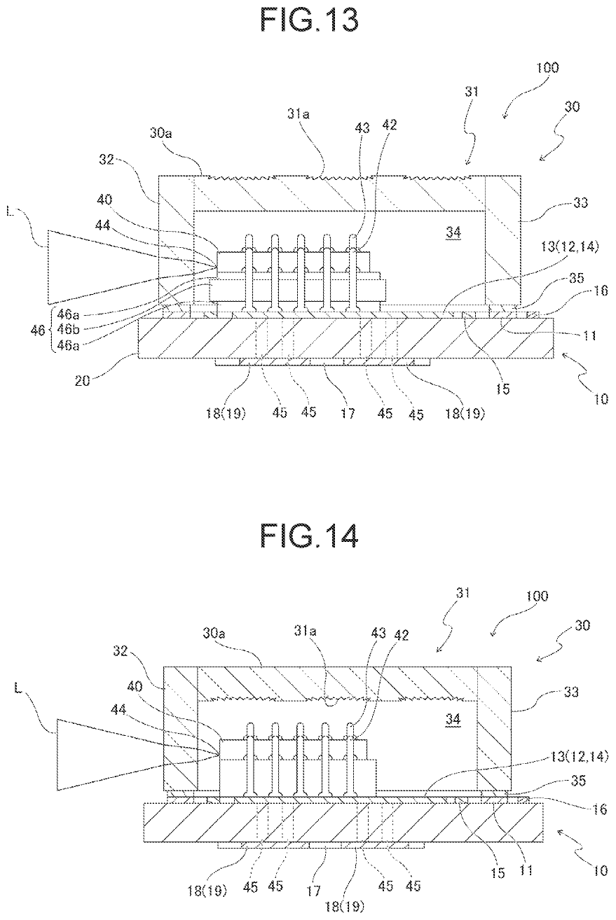

As illustrated in FIG. 13, the CAC submount 46 of the present embodiment is made of a CAC (Cu/AlN/Cu) material as described above. The CAC material is a material formed by stacking a Cu layer 46a, an AlN layer 46b, and a Cu layer 46a in three layers in a sandwich manner. As described above, the composite structure of copper (Cu) and sintered aluminum nitride (AlN) achieves both high thermal conductivity and insulating properties. Since the CAC submount 46 is configured as described above, it is possible to effectively dissipate heat from the semiconductor light emitting element 40. This makes it possible to reduce temperature rise, and thus, reliability is improved, and a long life is realized.

In addition, since the CAC submount 46 can be designed so that the linear thermal expansion coefficient of the CAC material matches the linear thermal expansion coefficient of the semiconductor light emitting element 40, the effective linear thermal expansion coefficient of the base unit 10 and the base unit 60 can be made close to that of the cover unit 30 or a heat sink (not illustrated) on which the semiconductor light emitting device 100 is mounted. This configuration can improve the strength of the bonding part and the heat cycle resistance.

The CAC submount 46 of the present embodiment is applicable to other embodiments, and may have a shape suitable for each embodiment.

The structure of the base unit 10 or the base unit 60 on which the CAC submount 46 of the present embodiment is mounted can be applied to other embodiments. The present embodiment is the same as the other embodiments except for the above. Thus, description thereof is omitted.

### <Structure of Cover Unit>

The structure of the cover unit 30 of the semiconductor light emitting device 100 according to the present embodiment is the same as that of the first embodiment. Thus, description thereof is omitted.

### <Overall Configuration of Base Unit and Cover Unit>

As the structure of the cover unit 30 of the semiconductor light emitting device 100 according to the present embodiment, the material of the submount 41 is changed from sintered aluminum nitride (AlN) to a CAC (Cu/AlN/Cu) material to form the CAC submount 46 as compared with other embodiments. The present embodiment is the same as the first embodiment except for the above. Thus, description thereof is omitted.

### 7. Seventh Embodiment of Semiconductor Light Emitting Device According to Present Disclosure

In the semiconductor light emitting device 100 according to the present embodiment, the rough surface 31a provided on the top surface 30a of the cover unit 30 is provided on the inner surface of the cover unit 30 as compared with other embodiments.

### <Structure of Base Unit>

The structure of the base unit 10 of the present embodiment is the same as that of the other embodiments, and is, for example, the same as that of the first embodiment. The base unit 60 according to the fifth embodiment may also be used. Thus, description thereof is omitted.

### <Structure of Cover Unit>

In the structure of the cover unit 30 of the semiconductor light emitting device 100 according to the present embodiment, as illustrated in FIG. 14, the rough surface 31a is provided on the upper surface of the inside of the body 31 of the cover unit 30. Although the example in which the rough surface 31a is provided on the upper surface of the inside of the body 31 is illustrated in this drawing, the position of the rough surface is not limited to the upper surface of the inside, and it may be provided on both the inner surface and the top surface 30a. In addition to this, the rough surface may be provided on both side surfaces.

With such a configuration, scattering of stray light can be enhanced. For example, when a light emitting device is mounted on a laser processing machine, unnecessary high-intensity reflected light from a workpiece may be generated. In such a case, by scattering the reflected light on the rough surface 31a provided on the inner surface and the outer peripheral surface, the light density can be reduced, and damage and failure due to the reflected laser light can be prevented.

Since the structure of the cover unit 30 of the present embodiment can be applied to other embodiments, description other than this is omitted.

### <Overall Configuration of Base Unit and Cover Unit>

The structure of the cover unit 30 of the present embodiment is different in the position where the rough surface 31a is provided and is the same as that of other embodiments except for this. Thus, the overall configurations of the base unit 10 and the cover unit 30 of the present embodiment are the same as those of the other embodiments, and thus, the description thereof other than this will be omitted.

### 8. Method for Producing Package of Semiconductor Light Emitting Device According to Present Disclosure

### <Method for Producing Base>

The base unit 10 of the semiconductor light emitting device 100 according to the present disclosure can be produced, for example, by molding aluminum nitride (AlN) into a shape as illustrated in FIG. 1 and sintering the aluminum nitride, using a known technique.

### <Method for Producing Cover Unit>

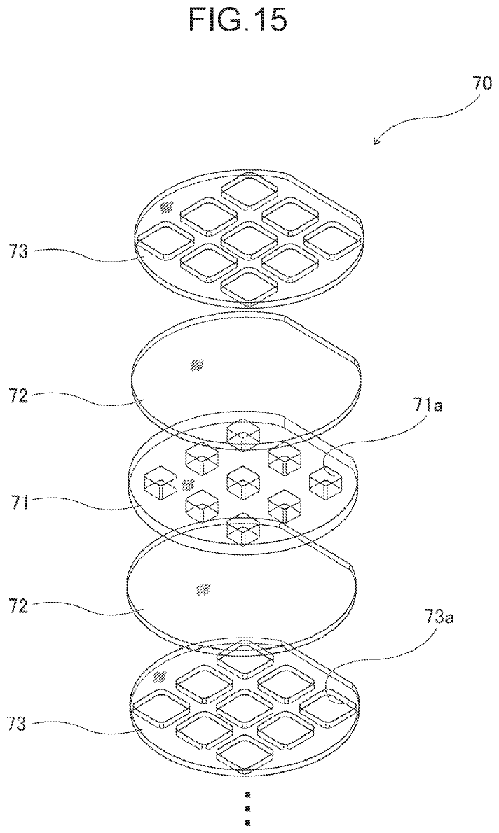

Next, a method for producing the cover unit 30 of the semiconductor light emitting device 100 according to the present disclosure will be described. FIGS. 15 to 25 are explanatory views of production steps of the cover unit 30 of the semiconductor light emitting device 100 according to the present disclosure.

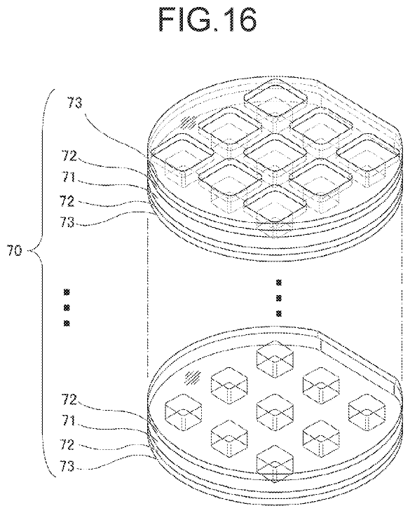

As illustrated in FIG. 15, the cover unit 30 can be formed by stacking three kinds of four wafer-like cover wafers 71 or the like to form a wafer stack 70 as illustrated in FIG. 16, and dividing the wafer stack by slicing the wafer stack in a vertical direction into individual pieces. Hereinafter, a detailed description will be given with reference to the drawings.

As illustrated in FIG. 15, three kinds of four spacer wafers 73, window glass wafers 72, cover wafers 71, and window glass wafers 72 are stacked in this order from bottom to top. The stacking of the three kinds of four sheets is performed as one stacking unit in the same manner below, and finally, the spacer wafer 73 is further stacked on the window glass wafer 72 and adhered. The adhesion of each layer is preferably an optical contact typically used in bonding of glass.

Here, the cover wafer 71 is a member constituting the body 31 in forming the cover unit 30. The cover wafer 71 is made of, for example, glass and is formed in a substantially disk shape with a partial arc cut off. Substantially square or rectangular square holes 71a having curved inner corners are formed, and regularly arrayed at predetermined intervals. The radius of curvature R2 of the curved inner corners is preferably 50 μm or more. Since this curved surface is processed by sandblasting or drilling, the process is facilitated by setting the predetermined radius of curvature R2. By having such a radius of curvature R2, it is possible to prevent stress from concentrating and generating cracks.

The window glass wafers 72 and 72 are members constituting the front window 32 and the rear window 33 of the cover unit 30. The window glass wafers 72 and 72 are made of glass, for example, and have the same outer peripheral shape as the cover wafer 71. However, no square hole is formed.

The spacer wafer 73 is a member that partitions the cover units 30 and protects the surfaces of the window glass wafers 72 and 72, and does not constitute the cover unit 30 because the spacer wafer is finally removed. The spacer wafer 73 is made of, for example, glass, and the shape of the outer periphery thereof is the same as that of the cover wafer 71. Substantially square or rectangular square holes 73a in which inner corners slightly larger than that of the square holes 71a of the cover wafer 71 are formed in a curved surface are formed so as to overlap the square holes 71a at the same pitch as the square holes 71a, and are regularly arrayed.

By stacking the stacking units over a plurality of layers in this manner, the wafer stack 70 is formed as illustrated in FIG. 16. The wafer stack 70 has, for example, a height of about 50 mm and a diameter of about 50 mm. In the wafer stack 70, a height corresponding to one cover unit 30 is about 5 mm. However, the above dimension of the wafer stack 70 is an example, and is not limited to this dimension.

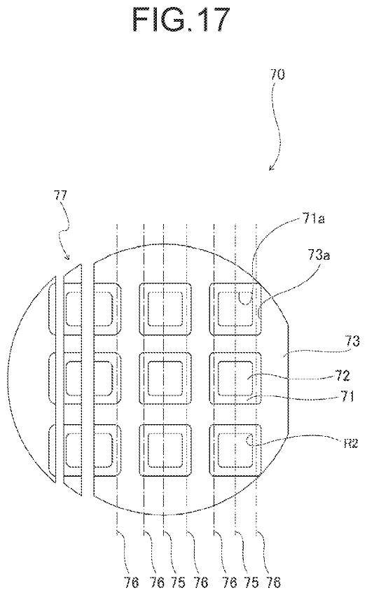

Next, as illustrated in FIG. 17, the wafer stack 70 is sliced in a longitudinal direction.

Specifically, the center lines of the square hole 71a and the square hole 73a are defined as a cutting line 75. Further, a bilaterally symmetrical position on the outer periphery of the square hole 71a and along the inner periphery of the square hole 73a is defined as a cutting line 76. Then, slicing is performed at the cutting line 75 and the cutting line 76.

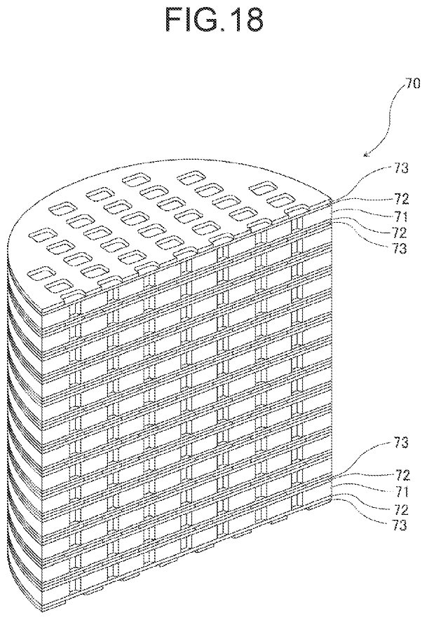

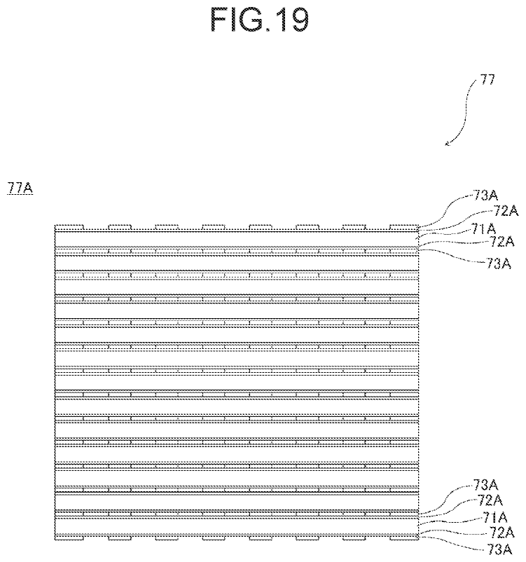

FIG. 18 is an external perspective view illustrating a cut surface when the wafer stack 70 is sliced along the cutting line 75. FIG. 19 is a view illustrating an upper surface 77A of the secondary wafer 77 when the wafer stack 70 is sliced at the cutting line 75 and the cutting line 76 as viewed from the cutting line 76 side to the cutting line 75 side. The surface sliced by the cutting line 76 becomes the top surface 30a of the cover unit 30 and becomes a surface to which the lens 51 is adhered via the tab 52.

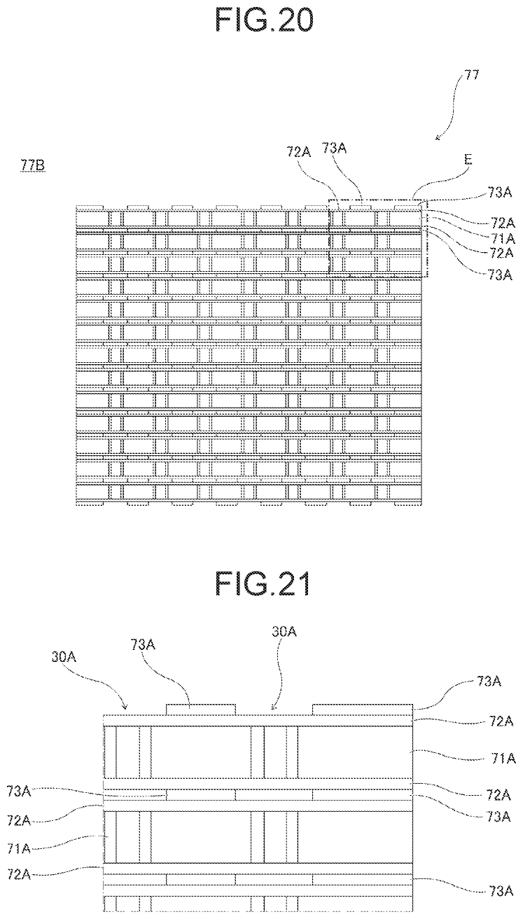

FIG. 20 is a view illustrating a bottom surface 77B of the secondary wafer 77 when the wafer stack 70 is sliced along the cutting line 75 and the cutting line 76 and viewed from the cutting line 75 side to the cutting line 76 side. The surface sliced by the cutting line 75 is a surface to be bonded to the base unit 10 or the base unit 60.

FIG. 21 is an enlarged view of a portion E surrounded by a one-dot chain line in an upper right corner of FIG. 20.

As illustrated in FIG. 21, in the secondary wafer 77, a spacer wafer piece 73A, a window glass wafer piece 72A, a cover wafer piece 71A, and a window glass wafer piece 72A are stacked in order from the bottom as one stacking unit, the stacking units are regularly arrayed in the vertical and horizontal directions, and the spacer wafer piece 73A is stacked at the uppermost portion.

The cover unit 30A corresponds to a semicircular columnar recess formed by being sandwiched between the stacking units. The recess of the cover unit 30A is formed by dividing the square hole 71a and the square hole 73a into two when the wafer stack 70 illustrated in FIG. 16 is sliced in the longitudinal direction at the cutting line 75. This recess forms the cavity 34 of the cover unit 30.

Next, the slice-cut bottom surface 77B illustrated in FIG. 20 of the secondary wafer 77 is polished. On the other hand, the upper surface 77A illustrated in FIG. 19 is finished into the rough surface 31a in order to adhere the lens unit 50. In this case, the arithmetic average roughness Ra of the rough surface 31a is 0.2 μm to 50 μm, preferably 0.2 μm to 5 μm.

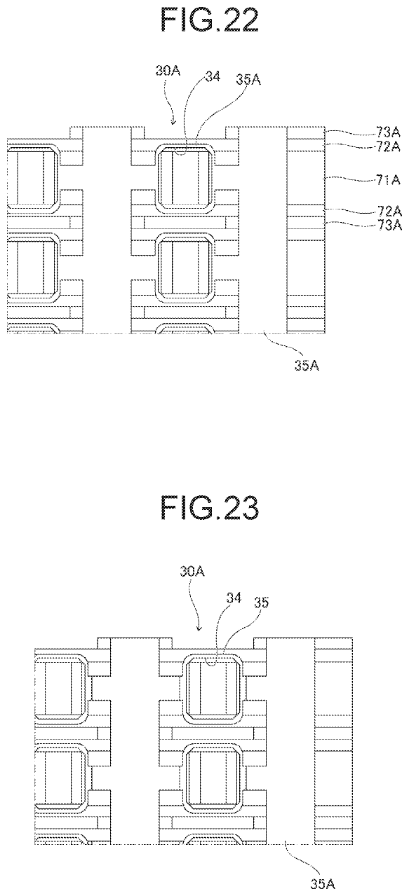

Next, as illustrated in FIG. 22, a base metal is formed on the bottom surface 77B illustrated in FIG. 20 using a photolithography, a film mask, or a metal mask. As a result, the base metal 35A of the annular base bonding solder pattern 35 for bonding with the cover bonding metal pattern 11 or the cover bonding pad 61 is formed at the peripheral edge of the recess forming the cavity 34.

As the base metal 35A, a stacked alloy made of chromium (Cr), titanium (Ti), molybdenum (Mo), platinum (Pt), nickel (Ni), gold (Au), or the like is typically used.

Next, as illustrated in FIG. 23, a substantially annular solder layer is formed on the base metal 35A using a photolithograph, a film mask, or a metal mask. As a result, the base bonding solder pattern 35 is formed on the peripheral edge of the recess forming the cavity 34.

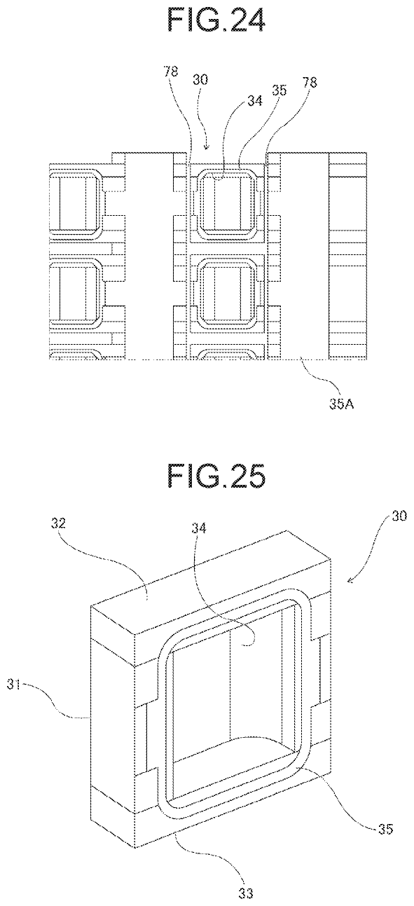

Next, as illustrated in FIG. 24, dicing cutting is performed in the longitudinal direction with both ends of the solder layer of the base bonding solder pattern 35 as a cutting line 78. The cover unit 30 as illustrated in FIG. 25 can be thus obtained.

Since the method for producing the cover unit 30 of the semiconductor light emitting device 100 according to the present disclosure includes the above-described steps, the following effects are obtained.

Since the spacer wafer 73 is inserted and stacked between the window glasses 72 and 72, the wafer stack 70 in which a large number of stacking units of wafers are stacked can be formed without damaging the surfaces of the window glasses 72 and 72. A large-sized secondary wafer 77 can be thus obtained.

In addition, since the size of the secondary wafer 77 can be increased, the workability is improved, and the cost can be reduced due to the mass production effect.

In addition, by using the spacer wafer 73, it is possible to produce the high-quality cover unit 30 having a flat and clean optical surface without a protrusion on the emission surface 44.

As described above, according to the present production method, a large amount of cover units 30 can be produced uniformly at low cost by a simple process.

### <Entire Assembly of Base Unit and Cover Unit>

The entire assembly of the base units 10 and 60 and the cover unit 30 can be performed by an extremely simple process as described with reference to FIG. 4, 8, or 12. In addition, in a case where the lens unit 50 is further added and assembled, it can also be performed by an extremely simple process as described with reference to FIG. 6 or FIG. 10.

Thus, according to the method for producing a package of the semiconductor light emitting device 100 according to the present disclosure, the package of the semiconductor light emitting device 100 can be produced in an extremely simple process and at low cost.

### 9. Positional Relationship of Light Emission Point of Package in Semiconductor Light Emitting Device According to Present Disclosure

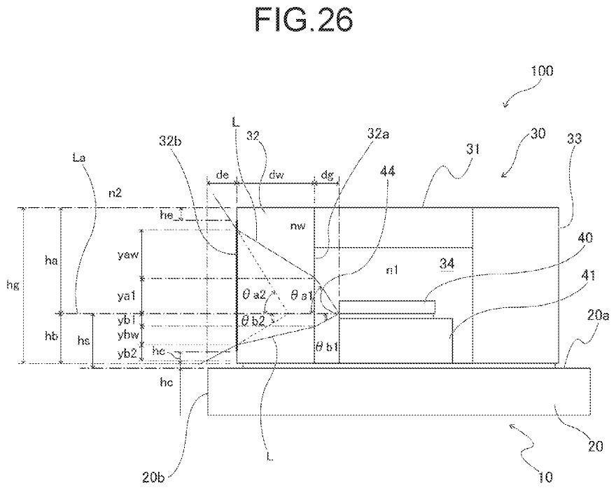

In the package of the semiconductor light emitting device 100 according to the first to seventh embodiments described above, the positional relationship of the emission surface 44, which is a light emission point, for preventing so-called “vignetting” will be described with reference to FIG. 26 using the first embodiment as an example.

FIG. 26 is a side view of the emission surface 44 of the semiconductor light emitting device 100. In the drawing, the submount 41 is bonded onto the device mounting pattern 12 on the upper surface 20a of the base unit 20, and the semiconductor light emitting element 40 is bonded onto the upper surface of the submount 41. In addition, the front window 32 is disposed facing the emission surface 44 of the semiconductor light emitting element 40. The rear window 33 is disposed on the back side of the emission surface 44.

The front window 32, the rear window 33, and the body 31 of the cover unit 30 form a cavity 34 which is a space for housing the semiconductor light emitting element 40. Here, the refractive index in the cavity 34 is defined as n1, the refractive index of the front window 32 is defined as nw, and the refractive index of the outside air is defined as n2.

In addition, as illustrated in the drawing, the height of the front window 32 is defined as hg, the distance from the optical axis La of the semiconductor light emitting element 40 to the upper surface 20a of the base unit 20 is defined as hs, the distance from the optical axis La to the upper end of the front window 32 is defined as ha, and the distance from the optical axis La to the lower end of the front window 32 is defined as hb.

A vertical direction divergence angle of the laser beam is defined as θ⊥, an upper vertical direction divergence angle of the optical axis La is defined as θa1, and a lower vertical direction divergence angle is defined as θb1. θa1+θb1=θ⊥ is satisfied. Here, it is assumed that the emitted light L emitted at the upper vertical direction divergence angle θa1 is refracted at the boundary (incident surface 32a) between the cavity 34 and the front window 32, travels inside the front window 32, is then refracted at the boundary (emission surface 32b) between the front window 32 and the outside air, and is emitted into the outside air. In this case, the upper vertical direction divergence angle viewed from the outside air is θa2. It is also assumed that the emitted light L emitted at the lower vertical direction divergence angle θb1 is refracted at the boundary (incident surface 32a) between the cavity 34 and the front window 32, travels inside the front window 32, is then refracted at the boundary (emission surface 32b) between the front window 32 and the outside air, and is emitted into the outside air. In this case, the lower vertical direction divergence angle viewed from the outside air is θb2.

In addition, the distance from the emission surface 44 of the semiconductor light emitting element 40 to the incident surface 32a of the front window 32 in the optical axis La direction is defined as dg, the distance from the incident surface 32a of the front window 32 to the emission surface 32b is defined as dw, and the distance from the emission surface 32b to the front end surface 20b of the base unit 20 is defined as de.

Then, each displacement amount with respect to the radiation angle of the semiconductor light emitting element 40 at the upper vertical direction divergence angle θa2 of the optical axis La viewed from the outside air is as follows.

The distance ya1 in a direction orthogonal to the optical axis La to the intersection of the emitted light L forming the angle θa1 and the incident surface 32a is

$$ya 1 = d g \cdot tan ( θ a 1 ) .$$

The distance yaw in a direction orthogonal to the optical axis La from the intersection of the emitted light L forming the angle θa1 and the incident surface 32a to the intersection of the emitted light L forming the angle θa2 and the emission surface 32b is

$$yaw = dw \cdot tan ( {sin}^{- 1} ( ( n 1 / nw ) sin ( θ a 1 ) ) ) .$$

On the other hand, each displacement amount with respect to the radiation angle of the semiconductor light emitting element 40 at the lower vertical direction divergence angle θb2 of the optical axis La is as follows.

The distance yb1 in a direction orthogonal to the optical axis La to the intersection of the emitted light L forming the angle θb1 and the incident surface 32a of the front window 32 is

$$yb 1 = d g \cdot tan ( θ b 1 ) .$$

The distance ybw in a direction orthogonal to the optical axis La from the intersection of the emitted light L forming the angle θb1 and the incident surface 32a to the intersection of the emitted light L forming the angle θb2 and the emission surface 32b is

$$ybw = dw \cdot tan ( {sin}^{- 1} ( ( n 1 / nw ) sin ( θ b 1 ) ) ) .$$

At this time, the distance yb2 in a direction orthogonal to the optical axis La from the intersection of the emitted light L forming the angle θb2 and the emission surface 32b to the intersection of the emitted light L forming the angle θb2 and a perpendicular line of the front end surface 20b of the base unit 20 is

$$yb 2 = de \cdot tan ( {sin}^{- 1} ( ( n 1 / n 2 ) sin ( θ b 1 ) ) )$$

Next, the restriction of the vertical direction divergence angle θ⊥ of the emitted light L with respect to the radiation angle of the semiconductor light emitting element 40 is as follows.

(1) It is necessary to be within the range of the height hg of the front window 32.

For this purpose, it is necessary to satisfy the following inequalities as a clear aperture CA.
ya1+yaw≤ha for the upper side of the optical axis La
yb1+ybw≤hb for the lower side of the optical axis La
where ha=hg−hb=hg−(hs−hc) and hb=hs−hc are satisfied.

(2) The emission surface 32b needs to be within the clear aperture CA.

For this purpose, when the ineffective region width is he, the following inequalities need to be satisfied.
ya1+yaw≤ha−he for the upper side of the optical axis La
yb1+ybw≤hb−he for the lower side of the optical axis La

(3) It is necessary not to overlap with the front end of the upper surface 20a of the base unit 20. This needs to be considered only when the front end surface 20b of the upper surface 20a protrudes more than the front window 32.

For this purpose, it is necessary to satisfy the following inequality only for the lower side of the optical axis La.

$$yb 1 + ybw + yb 2 \leq hs$$

The emitted light L of the semiconductor light emitting element 40 needs to satisfy the restriction with respect to the radiation angle and further satisfy the following inequalities.
(θ_{FWHM})/2≤θa1 for the upper side of the optical axis La
(θ_{FWHM})/2≤θb2 for the lower side of the optical axis La

In addition, the following inequalities are preferably satisfied.
θe/2≤θa1 for the upper side of the optical axis La
θe/2≤θb2 for the lower side of the optical axis La
where θ_{FWHM} is the full width at half maximum of the radiation angle, and θe is the full width at 1/e² of the radiation angle. e is Napier's constant.

By satisfying the above-described requirements, the semiconductor light emitting element 40 can perform appropriate emission. The above relationship also applies to the other embodiments.

Since the package of the semiconductor light emitting device 100 according to the present disclosure is configured to satisfy the above expressions, the semiconductor light emitting element 40 can perform appropriate emission without causing so-called vignetting.

### 10. Eighth Embodiment of Semiconductor Light Emitting Device According to Present Disclosure

An eighth embodiment relates to height adjustment of the optical axis La. When the optical element is disposed outside the semiconductor light emitting device 100, it may be better to raise the optical axis La, or it may be better to lower the optical axis La. When the optical axis La is raised by increasing the thickness of the submount 41 (or the CAC submount 46), thermal resistance of a portion of the submount 41 increases, and device performance may be deteriorated. When the optical axis La is lowered by thinning the submount 41, there is a problem of a limit of the thickness of the submount 41 that can be produced. It is desirable that the height of the optical axis La can be adjusted without changing the thickness of the submount 41.

The height of the optical axis La is defined by the thickness of the base unit 20 (first housing unit) and the thickness of the submount 41. If they are both 300 μm, the height of the optical axis La is 600 μm from the bottom surface of the base unit 20. If the optical axis La is too low, vignetting in which a part of the emitted light L is applied to the end portion of the base unit 20 or the mounting surface occurs, and the light use efficiency decreases. At the same time, light of the vignetting component becomes stray light, which is not preferable. When the optical axis La is too high, the optical system is generally susceptible to mechanical vibration, and the stability of the optical system is deteriorated. Since the optimum height of the optical axis La depends on the optical system design of the user, it is convenient if the optimum height of the optical axis La can be chosen as a product line.

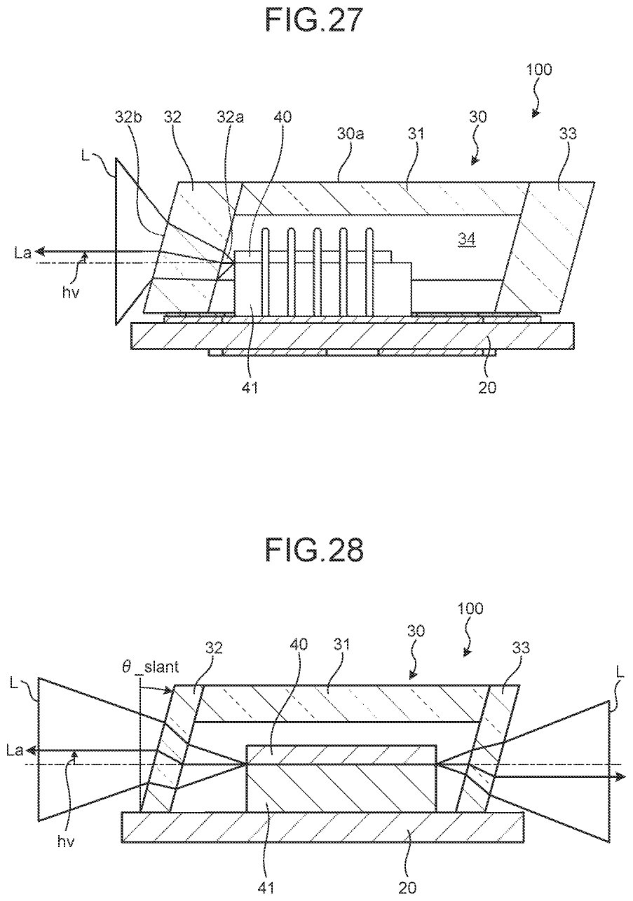

FIG. 27 is a diagram illustrating an example of a schematic configuration of the semiconductor light emitting device according to the eighth embodiment. The exemplified semiconductor light emitting device 100 is different from the configuration described above particularly in that the front window 32 and the rear window 33 are inclined with respect to the height direction of the semiconductor light emitting device 100. The height direction corresponds to the vertical direction in FIG. 27.

In this example, the top surface 30a of the body 31 of the cover unit 30 does not have the rough surface 31a. However, as described above, the top surface 30a may have the rough surface 31a.

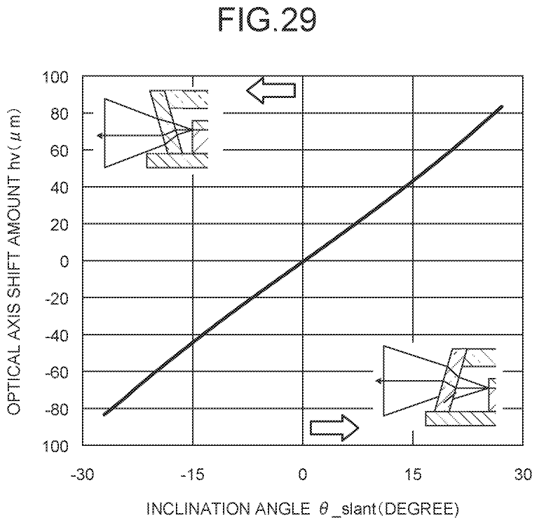

In FIG. 27, the emitted light L passing through the front window 32 is exemplified as the emitted light emitted from the semiconductor light emitting element 40. As understood, when the emitted light L passes through the front window 32, the height of the optical axis La changes. The amount of change in the height of the optical axis La is referred to as an optical axis shift amount hv in the drawing. The inclination of the front window 32 enables adjustment of the optical axis shift amount hv. This will be described with reference to FIGS. 28 and 29.

FIG. 28 is a diagram illustrating an inclination angle. The inclination angle of the front window 32 with respect to the height direction is referred to as an inclination angle θ_slant in the drawing. The inclination angle θ_slant is smaller than 90 degrees and larger than minus 90 degrees. In this example, as the inclination angle θ_slant increases from 0 degrees, the upper portion of the front window 32 (the connection portion with the body 31) approaches the semiconductor light emitting element 40, and the upper portion of the rear window 33 separates from the semiconductor light emitting element 40. The optical axis La of the emitted light L passing through the front window 32 increases by the magnitude of the optical axis shift amount hv. The optical axis La of the emitted light L passing through the rear window 33 decreases by the magnitude of the optical axis shift amount hv.

FIG. 29 is a graph illustrating an example of a relationship between an inclination angle and an optical axis shift amount. The horizontal axis of the graph represents the inclination angle θ_slant. The vertical axis of the graph represents the optical axis shift amount hv. The optical axis shift amount hv when the inclination angle θ_slant is 0 degrees is 0 μm. When the inclination angle θ_slant changes, the optical axis shift amount hv also changes. As the inclination angle θ_slant increases from 0 degrees, the optical axis shift amount hv also increases from 0 μm. As the inclination angle θ_slant decreases from 0 degrees, the optical axis shift amount hv also decreases from 0 μm.

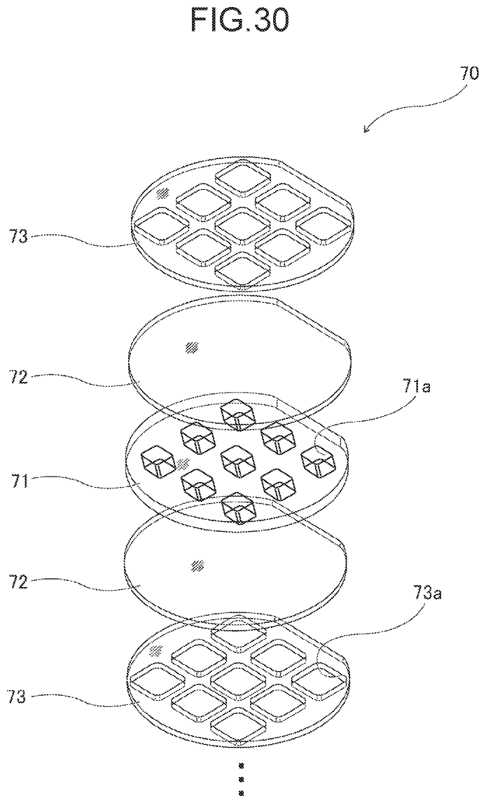

By changing the inclination angle θ_slant like this, the height of the optical axis La can be adjusted up and down by the optical axis shift amount hv. A method for producing the cover unit 30 including the inclined front window 32 and rear window 33 will be described with reference to FIGS. 30 to 34.

FIGS. 30 to 35 are views illustrating an example of a method for producing the cover unit. FIG. 30 is different from FIG. 15 described above in that the square hole 71a of the cover wafer 71 is inclined. In FIG. 31, the cover wafer 71 and the square hole 71a are illustrated in such a manner that the inclination is highlighted. The square hole 71a is drilled in the cover wafer 71 so as to have an inclination angle corresponding to the inclination angle θ_slant described above.

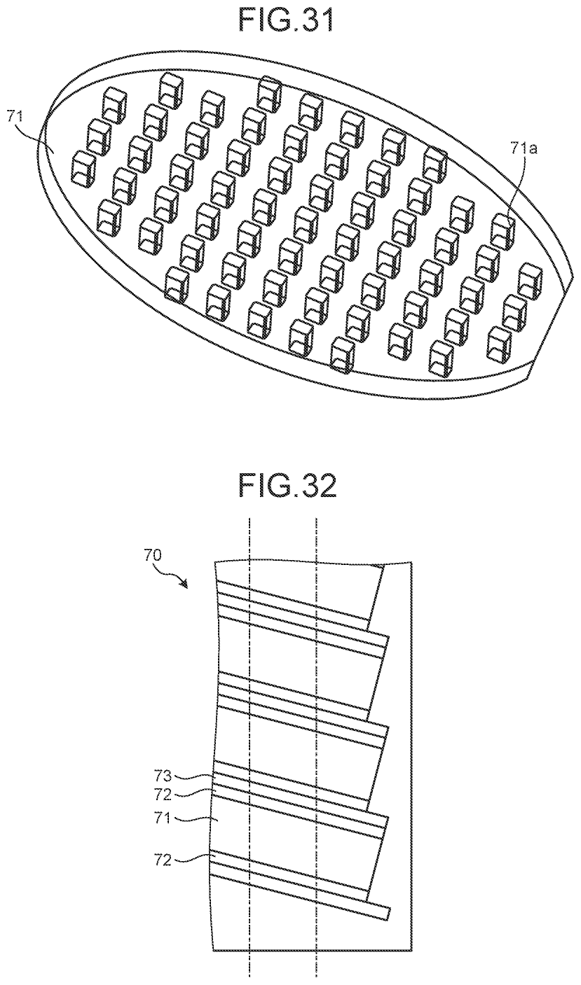

Four wafers of the window glass wafer 72, the cover wafer 71, the window glass wafer 72, and the spacer wafer 73 constitute a basic unit. The wafer stack 70 is obtained by stacking them. In this embodiment, as illustrated in FIG. 32, slicing is performed in a state in which the basic units are gradually shifted in the wafer plane direction. The shifting direction and the shifting amount correspond to the inclination direction and the inclination amount of the square hole 71a of the cover wafer 71. The slice-cutting direction is parallel to the square hole 71a of the cover wafer 71. In the drawing, the slice plane is schematically indicated by a one-dot chain line.

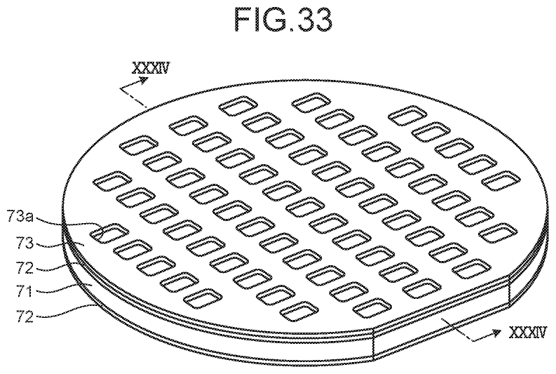

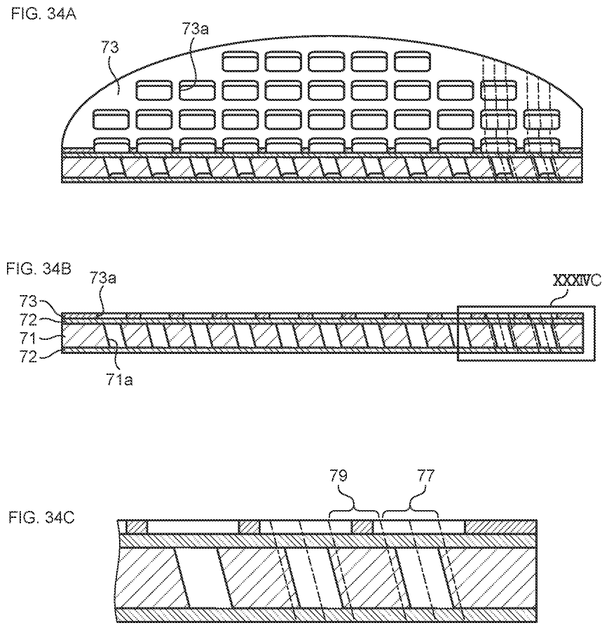

FIG. 33 schematically illustrates one basic unit. FIG. 34A schematically illustrates the basic unit including a section viewed obliquely. FIG. 34B schematically illustrates a section taken along the line XXXIV of FIG. 33. FIG. 34C schematically illustrates an enlarged portion surrounded by the line XXXIVC in FIG. 34B. As illustrated in FIGS. 34A to 34C, the square hole 71a of the cover wafer 71 is inclined, and each wafer is sliced and cut along the inclination direction. When the slicing is performed, if the cutting line is applied to the square hole 73a of the spacer wafer 73, the cutting line remains as a burr on the emission surface 32b. Thus, it is necessary to add a step of removing the burr, which leads to an increase in production cost. Thus, it is preferable to design the size and disposition of the square hole 73a so that the cut line does not overlap the square hole 73a of the spacer wafer 73.

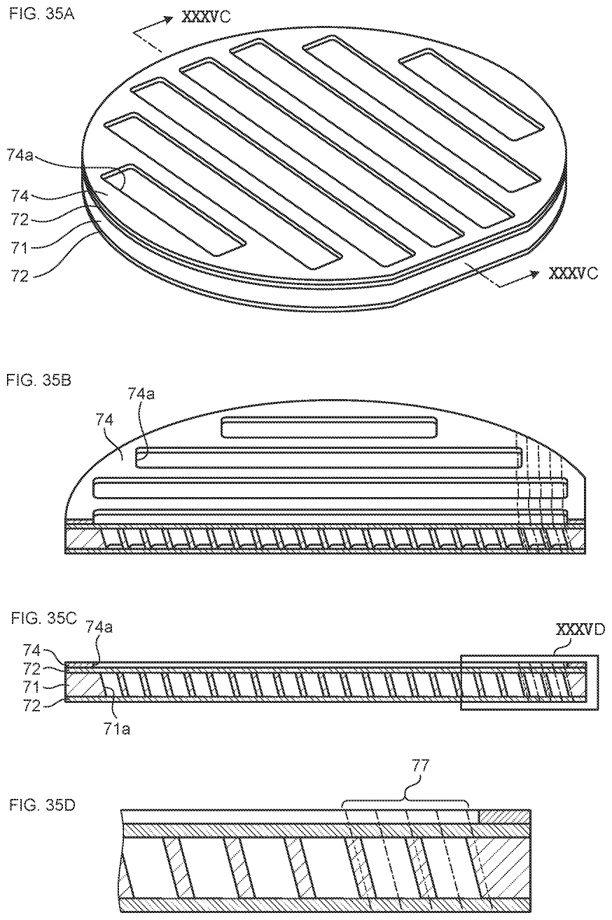

In addition, when the wafer stack 70 has sufficient rigidity against machining, the spacer wafer 73 can be replaced with a spacer wafer 74 having a long square hole 74a as illustrated in FIG. 35. FIG. 35A schematically illustrates one basic unit. FIG. 35B schematically illustrates the basic unit including a section viewed obliquely. FIG. 35C schematically illustrates a section taken along the line XXXVC of FIG. 35B. FIG. 35D schematically illustrates an enlarged portion surrounded by the line XXXVD in FIG. 35C. In this case, when the wafer stack 70 is sliced, an unnecessary portion 79 (FIG. 34C) is not generated, the number of adopted secondary wafers 77 can be increased, and thus, the cost can be reduced.

A secondary wafer (corresponding to the secondary wafer 77 in FIG. 19 and the like described above) is cut out by slicing. The cut secondary wafer is subjected to a metallizing step and a solder forming treatment, and then formed into individual pieces by dicing. The cover unit 30 is thus completed. By using the cover unit 30 produced in this manner, it is possible to obtain the semiconductor light emitting device 100 having the inclined front window 32 and rear window 33 as described above with reference to FIG. 27.

The configuration of the eighth embodiment described above may be combined with other embodiments as long as there is no contradiction.

### 11. Ninth Embodiment of Semiconductor Light Emitting Device According to Present Disclosure

A ninth embodiment relates to installation of an optical element. The semiconductor light emitting element 40 is, for example, a laser diode (LD) and has a large radiation angle. When the semiconductor light emitting device 100 including such a semiconductor light emitting element 40 is applied to an optical fiber coupled module used in a laser processing machine, collimation should be performed with a lens having a short focal length as much as possible in order to maintain high luminance for use. For this purpose, an optical element such as a lens may be formed directly on the emission surface 32b of the front window 32 of the cover unit 30 (or the emission surface of the rear window 33). In order to reduce the number of components and the adhesion process, the optical element may be integrally molded with the front window 32.

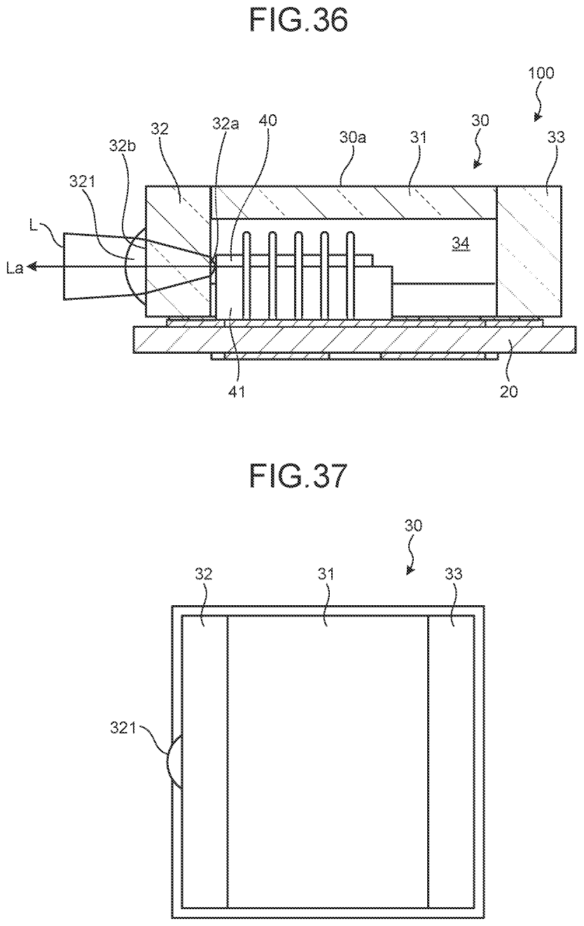

FIGS. 36 and 37 are diagrams illustrating an example of a schematic configuration of a semiconductor light emitting device according to the ninth embodiment. FIG. 37 illustrates the semiconductor light emitting device 100 as viewed from above. The exemplified semiconductor light emitting device 100 is different from the configuration described above in that the front window 32 includes an optical element 321.

The optical element 321 is formed on the front window 32, more specifically, on the emission surface 32b of the front window 32. The optical element 321 may be integrally molded with the front window 32. This is because an example of the material of the front window 32 and the rear window 33 is glass as described above, and the optical element 321 can be formed of the same material. In the examples illustrated in FIGS. 36 and 37, the optical element 321 is a convex lens.

Since the optical element 321 is formed in the front window 32, components of an optical system of an application product using the semiconductor light emitting device 100 can be reduced. In addition, since the relative position between the optical element 321 and the front window 32 is firmly fixed by integral molding, for example, high stability can be obtained.

Although not illustrated, when the emitted light L is output through the rear window 33, an optical element similar to the optical element 321 may be integrally molded on the rear window 33 to be directly provided on the rear window 33.

A method for producing the cover unit 30 including the front window 32 in which the optical element 321 is formed will be described. In the semiconductor light emitting device 100 in which the emitted light L of the semiconductor light emitting element 40 is output in the lateral direction, it is difficult to apply a press molding method, for example. In the press molding method, a clearance angle of a mold is required, and it is difficult to obtain the front window 32 and the rear window 33 that are straight in the vertical direction or the front window 32 and the rear window 33 that are inclined in the same direction (in parallel) as described above. In addition, when the optical element is directly formed on the front window 32 and the rear window 33, unevenness is generated on the front window 32 and the rear window 33, the mold cannot be pulled out, and production becomes difficult. In particular, as described above, when the front window 32 and the rear window 33 are inclined, there is a surface that is hidden with respect to the vapor deposition source of the AR coating device. There is a problem that uniformity of film formation between a surface to be hidden and a surface not to be hidden cannot be obtained, or film formation control becomes difficult.

In order to cope with the above problem, the cover unit 30 having the front window 32 in which the optical element 321 is formed is produced using the square hole 73a of the spacer wafer 73 described above. This will be described with reference to FIGS. 38 to 42.

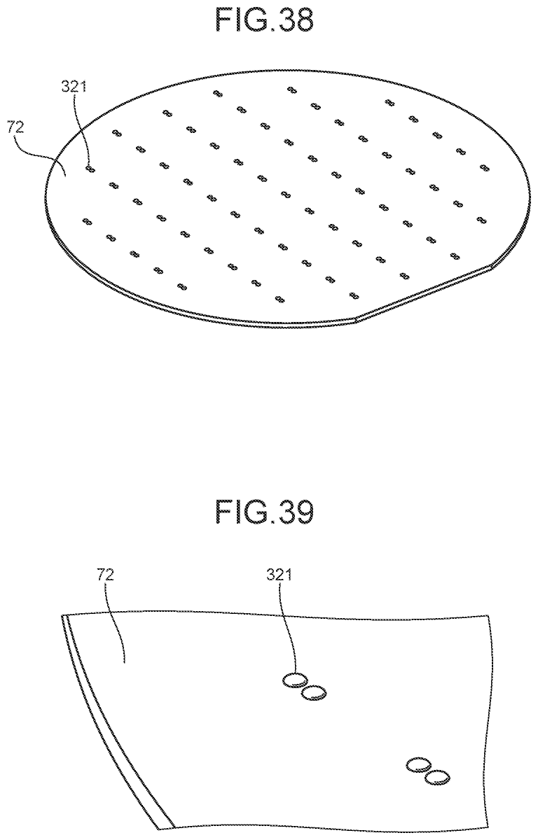

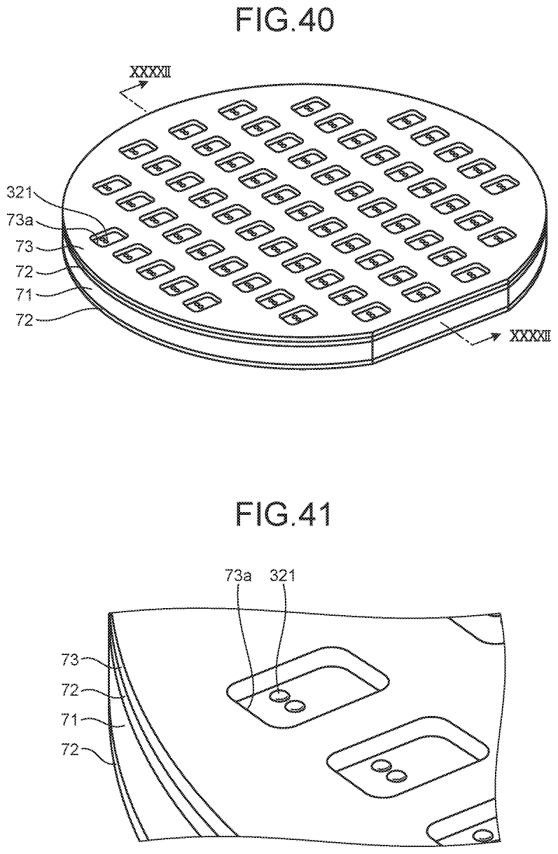

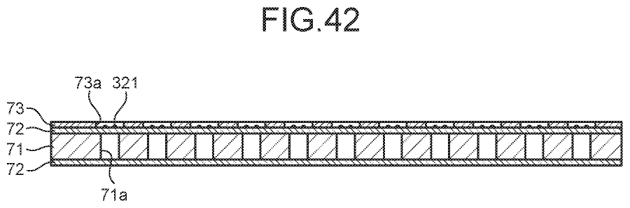

FIGS. 38 to 42 are views illustrating an example of a method for producing the cover unit. FIG. 38 schematically illustrates one window glass wafer 72. FIG. 39 schematically illustrates a part of the window glass wafer 72 in an enlarged manner. In FIGS. 40 to 42, one basic unit is schematically illustrated. FIG. 42 schematically illustrates a section taken along the line XXXXII of FIG. 40.

The optical element 321 is formed on the window glass wafer 72 (corresponding to the incident surface 32a of the front window 32). More specifically, the optical element 321 is formed on the window glass wafer 72 so as to be positioned in the square hole 73a of the spacer wafer 73. For the formation of the optical element 321, for example, etching, a molding method, or the like is used.

The square hole 73a of the spacer wafer 73 spatially absorbs the protrusion on the window glass wafer 72 caused by the optical element 321. This makes it possible to avoid contact of the optical element 321 with the basic unit stacked thereon, and for example, to maintain cleanness of the optical element 321.

Since the other production steps are as described above, the description thereof will not be repeated. By using the cover unit 30 having the front window 32 provided with the optical element 321, it is possible to obtain the semiconductor light emitting device 100 as described above with reference to FIGS. 36 and 37.

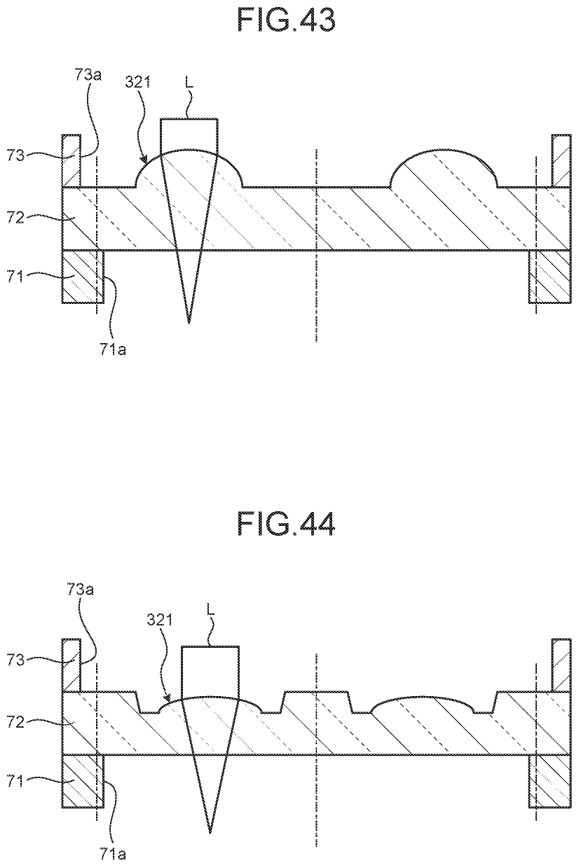

Various optical elements 321 may be formed on the window glass wafer 72. Some specific examples will be described with reference to FIGS. 43 to 48.

FIGS. 43 to 48 are diagrams illustrating examples of optical elements formed on a window glass wafer. The optical element 321 illustrated in FIG. 43 is a convex lens as in FIGS. 36 and 37 described above. The optical element 321 illustrated in FIG. 44 is a convex lens formed to sink from the surface of the window glass wafer 72. For example, when a convex lens is formed by molding on the flat window glass wafer 72 and then the surface is polished, such a shape is obtained.

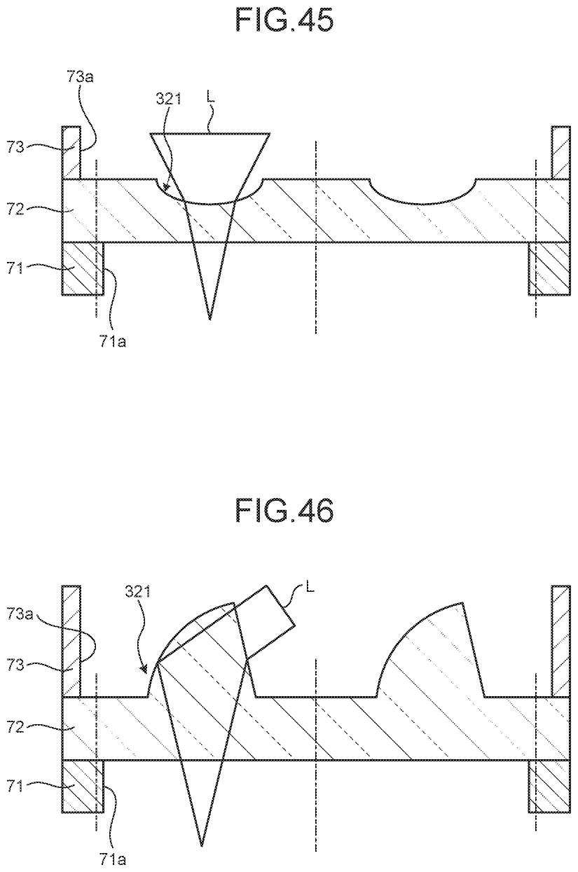

The optical element 321 illustrated in FIG. 45 is a concave lens. The optical element 321 illustrated in FIG. 46 includes a mirror (reflection structure). This configuration can change the direction of the emitted light L. When the protrusion of the optical element 321 is large, the above-described production method can be applied by increasing the thickness of the spacer wafer 73 as in this example.

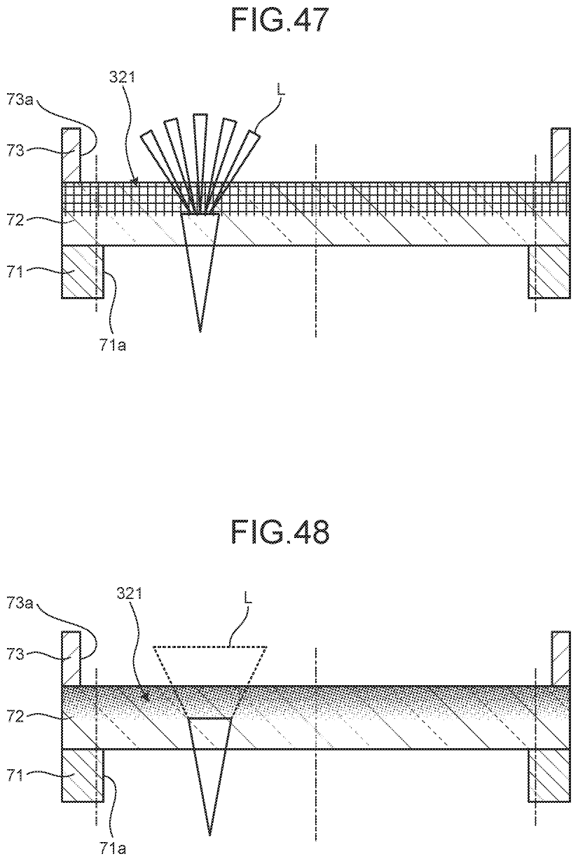

The optical element 321 illustrated in FIG. 47 includes a diffractive optical element. The emitted light L is output by being divided into a plurality of light beams. For example, the present technology can be applied to a so-called patterned light or the like, which is applied in face authentication of a mobile phone. The optical element 321 illustrated in FIG. 48 includes a wavelength conversion element. The wavelength of the emitted light L from the semiconductor light emitting element 40 is converted and output. An example of the wavelength conversion element is Ce:YAG that obtains white light in combination with a blue LD/LED.

The configuration of the ninth embodiment described above may be combined with other embodiments as long as there is no contradiction.

Finally, the description of each of the above-described embodiments is an example of the present disclosure, and the present disclosure is not limited to the above-described embodiments. Thus, it is needless to say that various modifications can be made according to the design and the like without departing from the technical idea according to the present disclosure even though they are other than the above-described embodiments. The effects described in the present specification are merely examples and are not restrictive of the disclosure herein, and other effects may be achieved.

The present technology may also take the following configurations.

(1) A semiconductor light emitting device comprising:
a semiconductor light emitting element including at least one light emitting region;
a first housing unit on which the semiconductor light emitting element is mounted, the first housing unit including a wiring structure with which the semiconductor light emitting element can be externally connected; and
a second housing unit having a lid shape, the second housing unit including a light emission surface and a rough surface configured to be able to transmit light, the second housing unit being bonded to the first housing unit.
   (2) The semiconductor light emitting device according to (1), wherein the second housing unit is provided with anti-reflection coating with respect to emitted light on one surface or both surfaces of the light emission surface.
   (3) The semiconductor light emitting device according to (1) or (2), wherein in the second housing unit, an inner corner formed by a top surface parallel to an optical axis and a side surface being orthogonal to each other is formed to have a radius of curvature of 50 μm or more.
   (4) The semiconductor light emitting device according to any one of (1) to (3), wherein a side surface forming the lid shape of the second housing unit has a thickness of 200 μm or more.
   (5) The semiconductor light emitting device according to any one of (1) to (4), wherein at least an outer periphery of a top surface of the second housing unit is formed into a rough surface.
   (6) The semiconductor light emitting device according to (5), wherein at least an inner peripheral surface of the second housing unit excluding the light emission surface is formed into the rough surface.
   (7) The semiconductor light emitting device according to (5) or (6), wherein the rough surface of the second housing unit has an arithmetic average roughness Ra of 0.2 μm to 50 μm.
   (8) The semiconductor light emitting device according to any one of (5) to (7), wherein the second housing unit is provided with a lens or a diffraction element formed to be able to transmit emitted light, the lens or the diffraction element being coupled and fixed to the rough surface directly or via a holding tab.
   (9) The semiconductor light emitting device according to any one of (1) to (8), wherein the second housing unit is made of a glass material.
   (10) The semiconductor light emitting device according to any one of (1) to (8), wherein the second housing unit is made of a glass material and silicon.
   (11) The semiconductor light emitting device according to (1), wherein the first housing unit has a ceramic substrate including the wiring structure in a single layer form or a stacked layer form.
   (12) The semiconductor light emitting device according to (1) or (11), wherein the first housing unit has a ceramic substrate including the wiring structure in a single layer form or a stacked layer form, and the ceramic substrate is provided with a wiring structure of a metal film having a thickness of 20 μm or more formed on a surface of the ceramic substrate.
   (13) The semiconductor light emitting device according to any one of (1) to (8), (11), and (12), wherein each of the first housing unit and the second housing unit includes a metal pattern or a metal pad formed in an annular shape formed on a peripheral edge of each of the first housing unit and the second housing unit, the metal pattern or the metal pad surrounding the semiconductor light emitting element and being capable of bonding the first housing unit and the second housing unit to each other, and the metal pattern or the metal pad has a width of 100 μm or more and has a radius of curvature of a corner of 100 μm or more.
   (14) The semiconductor light emitting device according to (13), wherein the metal pattern or the metal pad of each of the first housing unit and the second housing unit is formed in such a manner that the first housing unit and the second housing unit can be bonded to each other by soldering or an adhesive.
   (15) The semiconductor light emitting device according to (13) or (14), wherein the metal pattern or the metal pad of each of the first housing unit and the second housing unit is bonded and fixed with solder or a low-temperature sinterable fine particle metal and is airtightly sealed.
   (16) The semiconductor light emitting device according to any one of (13) to (15), wherein the first housing unit is configured to dispose an outer metal pattern on an outer periphery of the metal pattern formed in an annular shape, form a groove between the metal pattern formed in an annular shape and the outer metal pattern, and suck and hold solder or an adhesive overflowing when the second housing unit is bonded.
   (17) The semiconductor light emitting device according to any one of (13) to (16), wherein the first housing unit is configured to dispose an inner metal pattern on an inner periphery of the metal pattern formed in an annular shape, form a groove between the metal pattern formed in an annular shape and the inner metal pattern, and suck and hold solder or an adhesive overflowing when the second housing unit is bonded.
   (18) The semiconductor light emitting device according to any one of (1) to (17), in which
a positional relationship between the first housing unit, the second housing unit, a front window of the second housing unit, and the semiconductor light emitting element is as follows:
when an optical axis is La,
an upper vertical direction divergence angle of the optical axis La of emitted light is θa1,
an upper vertical direction divergence angle of the optical axis La as viewed from outside air is θa2,
a lower vertical direction divergence angle is θb2, and
an ineffective region width is he,
ya1+yaw≤ha−he is satisfied for an upper side of the optical axis La, and
yb1+ybw≤hb−he is satisfied for a lower side of the optical axis La,
where
ya1 is a distance in a direction orthogonal to the optical axis La to an intersection of the emitted light forming the angle θa1 and an incident surface of the front window,
yb1 is a distance in a direction orthogonal to the optical axis La to an intersection of the emitted light forming the angle θb1 and the incident surface of the front window,
yaw is a distance in a direction orthogonal to the optical axis La from an intersection of the emitted light forming the angle θa1 and the incident surface to an intersection of the emitted light forming the angle θa2 and an emission surface of the front window, and
ybw is a distance in a direction orthogonal to the optical axis La from an intersection of the emitted light forming the angle θb1 and the incident surface to an intersection of the emitted light forming the angle θb2 and the emission surface,
when a front end surface of an upper surface of the second housing unit protrudes more than the front window,
a relation of yb1+ybw+yb2≤hs is satisfied for the lower side of the optical axis La,
where
hs is a distance from the optical axis La to the upper surface of the second housing unit,
yb2 is a distance in a direction orthogonal to the optical axis La from an intersection of the emitted light forming the angle θb2 and the emission surface to an intersection of the emitted light forming the angle θb2 and a perpendicular line of the front end surface of the first housing unit, and further
(θ_{FWHM})/2≤θa1 is satisfied for the upper side of the optical axis La, and
(θ_{FWHM})/2≤θb2 is satisfied for the lower side of the optical axis La,
where
θ_{FWHM} is a full width at half maximum of an oblique angle,
θa1 is the upper vertical direction divergence angle of the optical axis La of the emitted light, and
θb2 is the lower vertical direction divergence angle of the optical axis La as viewed from outside air.
   (19) The semiconductor light emitting device according to (18), wherein the positional relationship between the first housing unit, the second housing unit, the front window of the second housing unit, and the semiconductor light emitting element satisfies
θe/2≤θa1 for the upper side of the optical axis La, and
θe/2≤θb2 for the lower side of the optical axis La.
θe is the full width at 1/e² of the radiation angle.
   (20) The semiconductor light emitting device according to any one of (1) to (19), wherein the semiconductor light emitting element is configured in such a manner that a wavelength of at least one light emitting point is different from a wavelength of another light emitting point.
   (21) The semiconductor light emitting device according to any one of (1) to (20), wherein the semiconductor light emitting element is configured to obtain emitted light from two surfaces.
   (22) The semiconductor light emitting device according to any one of (1) and (11) to (21), wherein the semiconductor light emitting element is mounted on a submount formed by stacking a copper (Cu)/sintered aluminum nitride (AlN)/copper (Cu) material, and the submount is mounted in the first housing unit.
   (23) A method for producing a package of a semiconductor light emitting device, the method including:
a step of stacking a plurality of layers of
a spacer wafer processed into a hole having a rectangular shape,
a first window glass wafer subjected to anti-reflection coating,
a cover unit wafer processed into a hole having a rectangular shape, and
a second window glass wafer subjected to anti-reflection coating
in this order to form a stack;
a step of forming a secondary wafer by slicing a center and an outer side of the hole formed in a rectangular shape in a stacking direction of the stack in the stacking direction;
a step of metallizing the secondary wafer into an annular metal pattern;
a step of performing a solder forming treatment of the metallized annular metal pattern; and
a step of dicing both side ends of the rectangular hole of the spacer wafer into individual pieces.
   (24) A semiconductor light emitting device including:
a semiconductor light emitting element including at least one light emitting region;
a first housing unit on which the semiconductor light emitting element is mounted, the first housing unit including a wiring structure with which the semiconductor light emitting element can be externally connected; and
a second housing unit having a lid shape, the second housing unit including a light emission surface configured to be able to transmit light, the second housing unit being bonded to the first housing unit, in which
the second housing unit includes a window including the light emission surface, and
the window is inclined with respect to a height direction of the semiconductor light emitting device.
   (25) The semiconductor light emitting device according to (24), in which
the window is inclined with respect to the height direction of the semiconductor light emitting element in such a manner as to shift a height of an optical axis of emitted light of the semiconductor light emitting element.
   (26) The semiconductor light emitting device according to any one of (1) to (7), and (9) to (25) from which (8) is not cited, in which
the second housing unit includes a window including the light emission surface, and
an optical element is formed in the window.
   (27) The semiconductor light emitting device according to (26), in which
the optical element is integrally molded with the window.
   (28) The semiconductor light emitting device according to (26) or (27), in which
the optical element includes a lens.
   (29) The semiconductor light emitting device according to any one of (26) to (28), in which
the optical element includes a mirror.
   (30) The semiconductor light emitting device according to any one of (26) to (29), in which
the optical element includes a diffractive optical element.
   (31) The semiconductor light emitting device according to any one of (26) to (30), in which
the optical element includes a wavelength conversion element.
   (32) The method for producing a package of the semiconductor light emitting device according to (23), in which
the cover wafer processed into a hole having a rectangular shape has a square hole inclined with respect to the stacking direction, and
in the step of forming the secondary wafer, four stacked wafers of the spacer wafer, the first window glass wafer, the cover unit wafer, and the spacer wafer are set as a basic unit, and the slicing is performed in parallel with the square hole in a state where each basic unit is gradually shifted and disposed to correspond to the inclination of the square hole in a wafer plane direction.
   (33) The method for producing a package of the semiconductor light emitting device according to (23), in which
the spacer wafer processed into a hole having a rectangular shape has a square hole, and
an optical element is formed on the first window glass wafer subjected to anti-flection coating to be positioned in the square hole of the spacer wafer.

### REFERENCE SIGNS LIST

10 BASE UNIT
11 COVER BONDING METAL PATTERN
11a OUTER GROOVE
11b INNER GROOVE
12 DEVICE MOUNTING METAL PATTERN
12a COUPLING PIECE
13 p-ELECTRODE WIRE BOND METAL PATTERN
14 n-ELECTRODE WIRE BOND METAL PATTERN
15 INNER METAL PATTERN
16 OUTER METAL PATTERN
16a INDEX MARK
17 HEAT RADIATION METAL PATTERN
18 p-ELECTRODE METAL PATTERN
19 n-ELECTRODE METAL PATTERN
20 BASE
20a UPPER SURFACE
20b FRONT END SURFACE
30 COVER UNIT
30a TOP SURFACE
31 BODY
31a ROUGH SURFACE
32 FRONT WINDOW
32a INCIDENT SURFACE
32b EMISSION SURFACE
33 REAR WINDOW
34 CAVITY
35 BASE BONDING SOLDER PATTERN
40 SEMICONDUCTOR LIGHT EMITTING ELEMENT
41 SUBMOUNT
42 p-ELECTRODE WIRE
43 n-ELECTRODE WIRE
44 EMISSION SURFACE
45 VIA
46 CAC SUBMOUNT
46a Cu LAYER
46b AlN LAYER
50 LENS UNIT
51 LENS
52 TAB
53 ADHESIVE
60 BASE UNIT
61 COVER BONDING PAD
62 DEVICE MOUNTING PAD
63 p-ELECTRODE WIRE BOND PAD
64 n-ELECTRODE WIRE BOND PAD
66 BASE
66a INDEX MARK
67 HEAT DISSIPATION PAD
68 P-ELECTRODE PAD
69 n-ELECTRODE PAD
70 WAFER STACK
71 COVER WAFER
71a SQUARE HOLE
72 WINDOW GLASS WAFER
73, 74 SPACER WAFER
73a SQUARE HOLE
74a LONG SQUARE HOLE
75, 76, 78 CUTTING LINE
77 SECONDARY WAFER
100 SEMICONDUCTOR LIGHT EMITTING DEVICE
321 OPTICAL ELEMENT
L EMITTED LIGHT

1. A semiconductor light emitting device comprising:
a semiconductor light emitting element including at least one light emitting region;
a first housing unit on which the semiconductor light emitting element is mounted, the first housing unit including a wiring structure with which the semiconductor light emitting element can be externally connected; and
a second housing unit having a lid shape, the second housing unit including a light emission surface and a rough surface configured to be able to transmit light, the second housing unit being bonded to the first housing unit.

2. The semiconductor light emitting device according to claim 1, wherein the second housing unit is provided with anti-reflection coating with respect to emitted light on one surface or both surfaces of the light emission surface.

3. The semiconductor light emitting device according to claim 1, wherein in the second housing unit, an inner corner formed by a top surface parallel to an optical axis and a side surface being orthogonal to each other is formed to have a radius of curvature of 50 μm or more.

4. The semiconductor light emitting device according to claim 1, wherein a side surface forming the lid shape of the second housing unit has a thickness of 200 μm or more.

5. The semiconductor light emitting device according to claim 1, wherein at least an outer periphery of a top surface of the second housing unit is formed into a rough surface.

6. The semiconductor light emitting device according to claim 5, wherein at least an inner peripheral surface of the second housing unit excluding the light emission surface is formed into the rough surface.

7. The semiconductor light emitting device according to claim 5, wherein the rough surface of the second housing unit has an arithmetic average roughness Ra of 0.2 μm to 50 μm.

8. The semiconductor light emitting device according to claim 5, wherein the second housing unit is provided with a lens or a diffraction element formed to be able to transmit emitted light, the lens or the diffraction element being coupled and fixed to the rough surface directly or via a holding tab.

9. The semiconductor light emitting device according to claim 1, wherein the second housing unit is made of a glass material.

10. The semiconductor light emitting device according to claim 1, wherein the second housing unit is made of a glass material and silicon.

11. The semiconductor light emitting device according to claim 1, wherein the first housing unit has a ceramic substrate including the wiring structure in a single layer form or a stacked layer form.

12. The semiconductor light emitting device according to claim 1, wherein the first housing unit has a ceramic substrate including the wiring structure in a single layer form or a stacked layer form, and the ceramic substrate is provided with a wiring structure of a metal film having a thickness of 20 μm or more formed on a surface of the ceramic substrate.

13. The semiconductor light emitting device according to claim 1, wherein each of the first housing unit and the second housing unit includes a metal pattern or a metal pad formed in an annular shape formed on a peripheral edge of each of the first housing unit and the second housing unit, the metal pattern or the metal pad surrounding the semiconductor light emitting element and being capable of bonding the first housing unit and the second housing unit to each other, and the metal pattern or the metal pad has a width of 100 μm or more and has a radius of curvature of a corner of 100 μm or more.

14. The semiconductor light emitting device according to claim 13, wherein the metal pattern or the metal pad of each of the first housing unit and the second housing unit is formed in such a manner that the first housing unit and the second housing unit can be bonded to each other by soldering or an adhesive.

15. The semiconductor light emitting device according to claim 13, wherein the metal pattern or the metal pad of each of the first housing unit and the second housing unit is bonded and fixed with solder or a low-temperature sinterable fine particle metal and is airtightly sealed.

16. The semiconductor light emitting device according to claim 13, wherein the first housing unit is configured to dispose an outer metal pattern on an outer periphery of the metal pattern formed in an annular shape, form a groove between the metal pattern formed in an annular shape and the outer metal pattern, and suck and hold solder or an adhesive overflowing when the second housing unit is bonded.

17. The semiconductor light emitting device according to claim 13, wherein the first housing unit is configured to dispose an inner metal pattern on an inner periphery of the metal pattern formed in an annular shape, form a groove between the metal pattern formed in an annular shape and the inner metal pattern, and suck and hold solder or an adhesive overflowing when the second housing unit is bonded.

18. The semiconductor light emitting device according to claim 1, wherein the semiconductor light emitting element is configured in such a manner that a wavelength of at least one light emitting point is different from a wavelength of another light emitting point.

19. The semiconductor light emitting device according to claim 1, wherein the semiconductor light emitting element is configured to obtain emitted light from two surfaces.

20. The semiconductor light emitting device according to claim 1, wherein the semiconductor light emitting element is mounted on a submount formed by stacking a copper (Cu)/sintered aluminum nitride (AlN)/copper (Cu) material, and the submount is mounted in the first housing unit.
